(19) United States
(12) Patent Application Publication
(10) Pub. No.: US 2026/0371533 A1
(43) Pub. Date: Nov. 19, 2026

(54) FLUID ENCLOSURE FOR COOLING ELECTRONIC EQUIPMENT OF A DATA CENTER COOLING SYSTEM

(71) Applicant: Tyco Fire & Security GmbH, Neuhausen am Rheinfall (CH)

(72) Inventor: Bryson Lee Sheaffer, Mechanicsburg, PA (US)

(21) Appl. No.: 19/678,105

(22) Filed: May 14, 2026

Related U.S. Application Data
(60) Provisional application No. 63/807,411, filed on May 16, 2025.

(51) Int. Cl. H05K 7/20

(52) U.S. Cl. CPC H05K 7/20809

(57) ABSTRACT

A fluid enclosure for a data center cooling system includes a housing defining an interior volume, where the housing is configured to receive a working fluid from a working fluid circuit of a vapor compression system and direct the working fluid into the interior volume to cool electronic equipment coupled to the fluid enclosure. The fluid enclosure also includes a reinforced region extending along a side of the housing, where the reinforced region includes a recessed surface and one or more ribs extending from the recessed surface, and the reinforced region is configured to distribute, across the side of the housing, a pressure load imparted by the working fluid within the interior volume.

### CROSS-REFERENCE TO RELATED APPLICATIONS

This application claims priority to and the benefit of U.S. Provisional Patent Application No. 63/807,411, entitled “HOUSING FOR COMPUTER ENCLOSURE OF COMPUTER COOLING SYSTEM,” filed on May 16, 2025, which is hereby incorporated by reference in its entirety for all purposes.

### BACKGROUND

This section is intended to introduce the reader to various aspects of art that may be related to various aspects of the present disclosure, which are described below. This discussion is believed to be helpful in providing the reader with background information to facilitate a better understanding of the various aspects of the present disclosure. Accordingly, it should be understood that these statements are to be read in this light, and not as admissions of prior art.

Heating, ventilation, air conditioning, and refrigeration (HVAC&R) systems, such as chiller systems (e.g., vapor compression systems), utilize a working fluid (e.g., a refrigerant) that changes phases between vapor, liquid, and combinations thereof in response to exposure to different temperatures and pressures within components of the chiller system. HVAC&R systems may include a compressor for circulating a working fluid (e.g., refrigerant) along a working fluid circuit and through heat exchangers of the HVAC&R system. For example, the HVAC&R system may include a first heat exchanger configured to receive the working fluid and a conditioning fluid to place the working fluid in the heat exchange relationship with the conditioning fluid. The conditioning fluid may be directed from the first heat exchanger to other equipment, such as air handlers, to condition other fluids, such as air or water. The HVAC&R system may also include a second heat exchanger configured to receive the working fluid and a cooling fluid to place the working fluid in the heat exchange relationship with the cooling fluid. In some embodiments, the cooling fluid may be water. Alternatively, the cooling fluid may be another fluid, such as air. Unfortunately, existing HVAC&R system configurations are susceptible to various drawbacks, such as limited heat transfer efficiency, incompatibility with certain heating or cooling loads, and so forth.

Further to the points above, data centers typically include racks of servers or other data center equipment that generate a substantial amount of heat during operation. Some data center cooling systems use fans to circulate cooled air through the server racks and provide cooling to the heat-generating equipment. Other data center cooling systems circulate a liquid coolant to the racks to draw heat directly from the heat-generating equipment or use a combination of air and liquid cooling. As data centers expand to support the rapid growth of cloud computing, artificial intelligence, and other modern applications having high computing loads and power densities, data centers need effective, energy-efficient cooling solutions that serve these applications while minimizing environmental impact.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In an embodiment, a fluid enclosure for a data center cooling system includes a housing defining an interior volume, where the housing is configured to receive a working fluid from a working fluid circuit of a vapor compression system and direct the working fluid into the interior volume to cool electronic equipment coupled to the fluid enclosure. The fluid enclosure also includes a reinforced region extending along a side of the housing, where the reinforced region includes a recessed surface and one or more ribs extending from the recessed surface, and the reinforced region is configured to distribute, across the side of the housing, a pressure load imparted by the working fluid within the interior volume.

In another embodiment, a data center cooling system includes a chiller system comprising a vapor compression system configured to cool a working fluid and circulate the working fluid along a working fluid circuit of the vapor compression system. The data center cooling system also includes a fluid enclosure disposed along the working fluid circuit. The fluid enclosure is configured to receive the working fluid and place the working fluid in a heat exchange relationship with a computer component disposed within or externally coupled to the fluid enclosure. The fluid enclosure includes a housing having a reinforced region configured to distribute a pressure load across a side of the housing.

In another embodiment, a fluid enclosure of a data center cooling system includes a housing configured to be disposed along a working fluid circuit of the data center cooling system, receive a working fluid circulated through the working fluid circuit, and transfer heat from an electronic component of a data center to the working fluid. The fluid enclosure further includes a reinforced region of the housing, wherein the reinforced region includes a recessed surface and a plurality of ribs extending from and along the recessed surface. The plurality of ribs includes a set of outer ribs defining a perimeter of the reinforced region and a set of interior ribs extending along the recessed surface from a first outer rib of the set of outer ribs to a second outer rib of the set of outer ribs. The reinforced region is configured to distribute a pressure load imparted by the working fluid within the housing across a side of the fluid enclosure.

Various refinements of the features noted above may exist in relation to various aspects of the present disclosure. Further features may also be incorporated in these various aspects as well. These refinements and additional features may exist individually or in any combination. For instance, various features discussed below in relation to one or more of the illustrated embodiments may be incorporated into any of the above-described aspects of the present disclosure alone or in any combination. The brief summary presented above is intended only to familiarize the reader with certain aspects and context of embodiments of the present disclosure without limitation to the claimed subject matter.

Various embodiments relate to an HVAC&R system for cooling electronic equipment (e.g., a cooling system for a data center, etc.) where a working fluid circuit (e.g., fluid circuit) extends between a compressor, a condenser, and a heat exchanger coupled to the electronic equipment (e.g., electronic component, computer component). The HVAC&R system may be a chiller, such as an air-cooled chiller.

In any of the embodiments disclosed herein:

The condenser may be an air-cooled condenser. The condenser may be remotely located from the compressor. The condenser may be a dry cooler.

The compressor may be an oil-less compressor.

The heat exchanger may be configured to provide single phase or two-phase heat exchange with respect to a working fluid, such as a refrigerant, as it passes through the heat exchanger. In some embodiments, the heat exchanger may be a plate heat exchanger coupled to a surface of a computer chip. In some embodiments, the heat exchanger may be a cold plate. In some embodiments, the heat exchanger may be configured to immerse the computer chip within the working fluid.

In some embodiments, the working fluid circuit may include a fluid enclosure, which may function as the heat exchanger configured to transfer heat from an electronic component (e.g., electronic equipment, computer chip, computer component) to the working fluid circulated along the working fluid circuit. The fluid enclosure may be disposed within a computer enclosure, a server rack, a frame or other support structure, a server tray, or any combination thereof.

In some embodiments, the fluid enclosure may include a housing defining an interior volume configured to receive the working fluid circulated along the working fluid circuit. The housing may include a reinforced region extending along at least one side of the housing. The reinforced region may include a recessed surface and one or more ribs extending from the recessed surface.

In some embodiments, the reinforced region may be configured to mitigate deformation of the housing in response to and/or that may otherwise be caused by an increase in the pressure load imparted by the working fluid (e.g., pressurized working fluid) circulated within the interior volume of the housing. The reinforced region may be configured to distribute the pressure load imparted by the working fluid within the housing across a side of the fluid enclosure (e.g., housing).

In some embodiments, the one or more ribs may include a plurality of interior ribs. The one or more ribs may include a plurality of outer ribs. The plurality of outer ribs may define a boundary of the reinforced region. The plurality of interior ribs may extend across the recessed surface to the boundary defined by the plurality of outer ribs.

In some embodiments, the reinforced region may include at least one interior rib of a plurality of interior ribs, which may extend diagonally along the recessed surface relative to at least one outer rib of a plurality of outer ribs.

In some embodiments, the reinforced region may include an intermediate rib extending from a first outer rib to a second outer rib. An interior rib may abut the intermediate rib. The intermediate rib may separate the reinforced region into a first sub-section and a second sub-section. A width of the intermediate rib may be greater than a width of an interior rib of the reinforced region.

In some embodiments, the reinforced region may be configured to align with and protect a chip cavity defined by the housing of the fluid enclosure.

In some embodiments, the reinforced region may be a geometric structure having a truss structure, a monocomb structure, or both.

In some embodiments, the fluid enclosure may be a cold plate configured to thermally couple to and support an electronic component (e.g., electronic equipment) disposed external to an interior volume of the fluid enclosure. In some embodiments, the electronic component may be physically coupled to an exterior of a housing of the fluid enclosure.

In some embodiments, the fluid enclosure may be a cold plate configured to circulate a working fluid through an interior volume of a housing and transfer heat from electronic equipment to the working fluid circulated through the interior volume via the housing (e.g., a side of the housing) to cool the electronic equipment.

The fluid enclosure may include a housing and may be configured to contain and support electronic equipment (e.g., an electronic component) disposed within an interior volume of the housing. The fluid enclosure may receive working fluid from a working fluid circuit and place the working fluid within the interior volume in direct thermal contact with the electronic equipment, such as via immersion of the electronic equipment within the working fluid.

The housing of the fluid enclosure may include cast aluminum. The cast aluminum may define the reinforced region.

The housing of the fluid enclosure may include a plurality of sides that collectively define an interior volume of the housing. A first side of the plurality of sides may be a top side of the fluid enclosure (e.g., housing). A second side of the plurality of sides may be a bottom side of the fluid enclosure (e.g., housing). A third side of the plurality of sides may be a lateral side of the fluid enclosure (e.g., housing). Respective widths of the top side and the bottom side may be less than a width of the lateral side.

### BRIEF DESCRIPTION OF THE DRAWINGS

Various aspects of this disclosure may be better understood upon reading the following detailed description and upon reference to the drawings in which:

FIG. 1 is a perspective view of an embodiment of a data center room including racks served by a data center cooling system, in accordance with an aspect of the present disclosure;

FIG. 2 is a block diagram of an embodiment of a data center cooling system, such as the data center cooling system of FIG. 1, in accordance with an aspect of the present disclosure;

FIG. 3 is a block diagram of an embodiment of a rack of a data center room, such as the data center room of FIG. 1, in greater detail, in accordance with an aspect of the present disclosure;

FIG. 4 is a perspective view of an embodiment of a server tray which can be installed in the racks of a data center room, such as the data center room of FIG. 1, in accordance with an aspect of the present disclosure;

FIG. 5 is a block diagram of an embodiment of a liquid cooling circuit which can be used in a data center cooling system, such as the data center cooling system of FIG. 1, in accordance with an aspect of the present disclosure;

FIG. 6 is a block diagram of an embodiment of an air cooling circuit which can be used in a data center cooling system, such as the data center cooling system of FIG. 1, in accordance with an aspect of the present disclosure;

FIG. 7 is a schematic of an embodiment of an HVAC&R system including a chiller system configured to provide cooling to electronic equipment, in accordance with an aspect of the present disclosure;

FIG. 8 is a schematic of an embodiment of an HVAC&R system including a chiller system configured to provide cooling to electronic equipment, in accordance with an aspect of the present disclosure;

FIG. 9 is a perspective view of an embodiment of a cabinet including a mounting system configured to support electronic equipment, in accordance with an aspect of the present disclosure;

FIG. 10 is a schematic plan view of an embodiment of a computer enclosure configured to house electronic equipment and receive a fluid from a chiller system, in accordance with an aspect of the present disclosure;

FIG. 11 are perspective views of an embodiment of a computer enclosure configured to house electronic equipment and having one or more reinforced regions, in accordance with an aspect of the present disclosure;

FIG. 12 is an exploded perspective view of an embodiment of a computer cooling assembly having a computer enclosure configured to support one or more cold plates configured to enable cooling of electronic equipment coupled thereto, in accordance with an aspect of the present disclosure;

FIG. 13 is a cross-sectional side view of an embodiment of a computer component heat exchanger, such as a computer enclosure and/or cold plate, illustrating forces acting on the computer component heat exchanger, in accordance with an aspect of the present disclosure;

FIG. 14 is a perspective view of an embodiment of a reinforced region of a computer component heat exchanger, in accordance with aspects of the present disclosure;

FIG. 15 is a top view of an embodiment of a reinforced region of a computer component heat exchanger, in accordance with an aspect of the present disclosure; and

FIG. 16 is a side view of an embodiment of a reinforced region of a computer component heat exchanger, in accordance with an aspect of the present disclosure.

### DETAILED DESCRIPTION

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers’ specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features.

As used herein, the terms “approximately,” “generally,” “substantially,” and so forth, are intended to convey that the property value being described may be within a relatively small range of the property value, as those of ordinary skill would understand. For example, when a property value is described as being “approximately” equal to (or, for example, “substantially similar” to) a given value, this is intended to convey that the property value may be within +/- 5%, within +/- 4%, within +/- 3%, within +/- 2%, within +/- 1%, or even closer, of the given value. Similarly, when a given feature is described as being “substantially parallel” to another feature, “generally perpendicular” to another feature, and so forth, this is intended to convey that the given feature is within +/- 5%, within +/- 4%, within +/- 3%, within +/- 2%, within +/- 1%, or even closer, to having the described nature, such as being parallel to another feature, being perpendicular to another feature, and so forth. Mathematical terms, such as “parallel” and “perpendicular,” should not be rigidly interpreted in a strict mathematical sense, but should instead be interpreted as one of ordinary skill in the art would interpret such terms. For example, one of ordinary skill in the art would understand that two lines that are substantially parallel to each other are parallel to a substantial degree but may have minor deviation from exactly parallel.

As used herein, an HVAC&R system may include any number of components configured to enable regulation of one or more parameters related to climate characteristics, such as temperature, humidity, air flow, pressure, air quality, and so forth. For example, an “HVAC&R system” as used herein may be defined as a system configured to perform operations including one or more of heating, cooling, ventilation, dehumidification, pressurization, refrigeration, filtration, or any combination thereof. Indeed, certain HVAC&R systems incorporating the present techniques may be configured to perform certain operations (e.g., cooling) but not others (e.g., heating). Components or parts of an “HVAC&R system” may include, but are not limited to, all, some of, or individual parts such as a heat exchanger, a fluid flow control device, such as a valve, a sensor configured to detect a climate characteristic or operating parameter, a filter, a control device configured to regulate operation of an HVAC&R system component, a component configured to enable regulation of one or more climate characteristics, or a combination thereof. The embodiments described herein may be utilized in a variety of applications to control climate characteristics, such as residential, commercial, industrial, transportation, or other applications where climate control is desired.

A heating, ventilation, air conditioning, and/or refrigeration (HVAC&R) system (e.g., chiller system) may be implemented to thermally regulate a space within a building, home, or other suitable structure. HVAC&R systems may also be utilized to thermally regulate systems and/or components that demand thermal conditioning (e.g., provide cooling/heat rejection to components within a facility such as a data center). In general, HVAC&R systems include a vapor compression system (e.g., vapor compression circuit) that transfers thermal energy between a working fluid (e.g., refrigerant) and a fluid to be conditioned, such as water, air, or another suitable fluid. The vapor compression system may include one or more heat exchangers, such as a condenser and an evaporator, that are fluidly coupled to one another via a working fluid circuit (e.g., refrigerant circuit, one or more conduits). The vapor compression system may also include a compressor configured to circulate the working fluid through the working fluid circuit and thereby enable the transfer of thermal energy between the condenser and the evaporator and respective fluids directed through the condenser and the evaporator.

In some applications, the HVAC&R system may be or include a chiller system configured to condition a conditioning fluid (e.g., water) that is directed to downstream equipment, such as air handlers, computer equipment, heat exchangers, and/or other components configured to utilize the conditioning fluid to cool a conditioned space, another device or component (e.g., computer system, computer server, electronic equipment), or both. To this end, the chiller system may include an evaporator configured to transfer heat from the conditioning fluid to a working fluid circulated through the chiller system. The chiller system may also include a condenser configured to transfer heat from the working fluid to a cooling fluid. In some applications, the cooling fluid may be water (e.g., water-cooled chiller). Alternatively, the cooling fluid may be air (e.g., air-cooled chiller). In yet further implementations, combinations of air and water may be used as the cooling fluid for the chiller system.

In some implementations, HVAC&R systems, such as chiller systems, dry coolers, and/or cooling towers, are utilized to cool electronic equipment. For example, electronic equipment, such as computers, servers, storage devices, network equipment, power supplies, computing systems, and/or information technology (IT) hardware or infrastructure, may generate substantial amounts of heat during operation. In order to facilitate proper operation of such electronic equipment, the generated heat should be transferred and/or rejected to another suitable location or environment in order to maintain operating temperatures of the electronic equipment below relevant threshold temperatures. It will be appreciated that some facilities, such as data centers, may house considerable amounts of electronic equipment that generate heat in a relatively small area. Accordingly, chiller systems may be implemented, along with other cooling system components, to enable rejection of heat generated by such electronic equipment.

In some implementations, the chiller systems may operate to cool a fluid that is placed in a heat exchange relationship with the electronic equipment. For example, some cooling systems may include coolant distribution units (CDUs) that include a heat exchanger configured to transfer heat between a conditioning fluid generated (e.g., cooled) by the chiller system and a coolant that is placed in a heat exchange relationship with the electronic equipment. The conditioning fluid cooled by the chiller system may be a flow of water (e.g., facility water) supplied or provided by a facility housing the electronic equipment (e.g., data center), and the coolant may be another flow of water (e.g., technical water, IT water) suitable for placing in a heat exchange relationship with the electronic equipment. The flow of water cooled by the chiller system may not be suitable for placing in a heat exchange relationship with the electronic equipment. Therefore, the heat exchanger of the CDU may isolate the conditioning fluid from the electronic equipment.

Additionally, or alternatively, some cooling systems may include a chiller system having a working fluid circuit configured to circulate a working fluid (e.g., refrigerant) to cool a conditioning fluid (e.g., water, glycol, water and glycol mixture), and a conditioning fluid circuit configured to circulate the conditioning fluid between the chiller system and the electronic equipment. More specifically, the conditioning fluid circuit is configured to place the conditioning fluid in a heat exchange relationship with the working fluid circulated through the working fluid circuit of the chiller system and is also configured to place the conditioning fluid in a heat exchange relationship with the electronic equipment. In other embodiments, the chiller system may be configured to cool the working fluid and direct the working fluid to the electronic equipment to place the working fluid in a heat exchange relationship with the electronic equipment, such as via a chilled plate, a tube, a flow path, a channel, a vessel, and/or immersion cooling techniques. In such embodiments, the cooling system may or may not include a conditioning fluid circuit configured to place a conditioning fluid in a heat exchange relationship with the electronic equipment.

In certain cases, the fluid (e.g., working fluid, conditioning fluid, two-phase fluid, cooling water, IT fluid [e.g., specialized working fluid for electronic components]) supplied to cool the electronic equipment may be directed to a computer enclosure (e.g., blade, fluid enclosure) configured to house (e.g., protect, surround, enclose) and/or support the electronic equipment. The working fluid and/or conditioning fluid may be directed under pressure toward the computer enclosure, whereby heat generated by the electronic equipment disposed within and/or thermally coupled to the computer enclosure is transferred to the working fluid and/or the conditioning fluid. In this way, electronic equipment disposed within and/or thermally coupled to the computer enclosure may be cooled. For example, in certain embodiments, the computer enclosure may correspond to a pressure vessel and/or may include or define a number of pressure vessels, whereby each pressure vessel is configured to house and/or contain one or more computer components (e.g., computer chips, heat-generating components). In such embodiments, the working fluid and/or conditioning fluid may be directed toward the pressure vessel(s) defined by the computer enclosure (e.g., provided directly into an interior volume of the pressure vessel(s)) to provide immersion cooling for the electronic equipment disposed within the computer enclosure (e.g., disposed within the pressure vessel(s) defined by the computer enclosure).

Additionally, or alternatively, the computer enclosure may include one or more heat exchangers (e.g., cold plates, chilled plates, chilled tubes) disposed therein and/or mounted thereto, whereby the heat exchangers are in thermal communication with the one or more computer components. For example, in certain embodiments, the computer enclosure may correspond to a frame or housing configured to support (e.g., house, enclose) one or more heat exchangers, such as one or more cold plates. The cold plates may configured to receive the working fluid and/or conditioning fluid and place the working fluid and/or conditioning fluid in a heat exchange relationship with the one or more computer components. For example, the one or more computer components may be thermally coupled to the cold plates. Said another way, the one or more computer components may be positioned external to the cold plates and/or the computer enclosure and may be coupled to the cold plates in a manner that enables heat exchange between the computer component and the fluid (e.g., working fluid, conditioning fluid) directed through the cold plate. In this way, heat generated by the computer components may be transferred to the working fluid and/or conditioning fluid directed through the cold plate, thereby cooling the computer components.

In any case, the working fluid and/or the conditioning fluid may be directed into the computer enclosure (e.g., into the pressure vessel(s) defined by the computer enclosure) and/or into the cold plate(s) (e.g., into a fluid enclosure) under pressure, thereby increasing a pressure within the interior volume of the computer enclosure (e.g., increasing a pressure within an interior volume of the pressure vessel(s) defined by the computer enclosure) and/or cold plates. Unfortunately, some computer enclosures and/or cold plates, each of which may generally be referred to as a fluid enclosure) may be susceptible to various drawbacks, including a limited ability to withstand increased pressures or forces imparted to one or more portions of the computer enclosures (e.g., portions corresponding to the one or more pressure vessels) and/or cold plates. Additionally, the weight (e.g., mass) and/or footprint of certain computer enclosures, such as computer enclosures that correspond to and/or define one or more pressure vessels and/or computer enclosures that support one or more cold plates, may limit a serviceability of the computer enclosures. For example, the weight of some computer enclosures may exceed certain mass thresholds, such that individuals tasked with servicing the electronic equipment disposed within and/or thermally coupled to the computer enclosure may be unable to independently maneuver (e.g., lift, move) and/or service the computer enclosure.

Accordingly, present embodiments are directed toward an improved computer enclosure and/or cold plate (e.g., fluid enclosure) for cooling systems that provide cooling to electronic equipment disposed within and/or thermally coupled to the computer enclosure and/or cold plate. More particularly, embodiments discussed herein may include a computer enclosure and/or cold plate with one or more reinforced regions configured to provide structural rigidity to the computer enclosure and/or cold plate while limiting an amount of material utilized to form the computer enclosure and/or cold plate. In this way, a mass (e.g., weight and/or footprint) of the computer enclosure and/or cold plate supported by the computer enclosure may be limited or reduced, thereby improving maintenance and/or serviceability of the computer enclosure and/or cold plate, as well as the electronic equipment disposed therein and/or thermally coupled thereto. Further, the reinforced regions may be configured to maintain a structural integrity of the computer enclosure and/or cold plate as pressures within the computer enclosure and/or cold plate fluctuate and/or increase (e.g., based on the introduction of working fluid and/or conditioning fluid, based on cooling demands associated with the electronic equipment disposed within the computer enclosure).

For example, embodiments of the computer enclosure and/or cold plate discussed herein may include a number of sides that collectively define an interior volume of the computer enclosure or cold plate. One or more of the sides may include one or more reinforced regions. As discussed herein, a reinforced region may correspond to one or more physical structures or features (e.g., monocomb structure, truss structure, geometric feature) configured to distribute a pressure load or force across a side of the computer enclosure or cold plate. In certain embodiments, the reinforced region may include a recessed surface (e.g., flat surface) and one or more ribs (e.g., reinforcement ribs, extensions) extending along and from the recessed surface (e.g., in various directions). One or more of the ribs (e.g., perimeter ribs, peripheral ribs) may extend from and along an outer perimeter of the recessed surface to define an outer boundary or perimeter of the reinforced region. Under certain operating conditions, the ribs extending along and/or across the recessed surface may be configured to engage with the perimeter ribs to increase the structural rigidity of the computer enclosure or cold plate. For example, during operation of the cooling system, as working fluid and/or conditioning fluid is directed into the computing enclosure or cold plate, the pressure within the interior volume of the computer enclosure or cold plate may increase. As the pressure increases, the computer enclosure or cold plate may expand, and the interior ribs in abutment and/or engaged with the perimeter ribs may mechanically distribute the pressure load, thereby limiting an amount of bowing, expansion, and/or deformation of the recessed portions and the side of the computer enclosure or cold plate generally. Thus, the reinforced regions may enable the structural integrity of the computer enclosure or cold plate to be maintained while limiting an amount of material (e.g., limiting a mass) associated with the computer enclosure or cold plate. In this way, manufacturing costs of computer enclosures or cold plates may be reduced and serviceability of the computer enclosure or cold plate, as well as the electronic equipment disposed therein or thermally coupled thereto, may be improved.

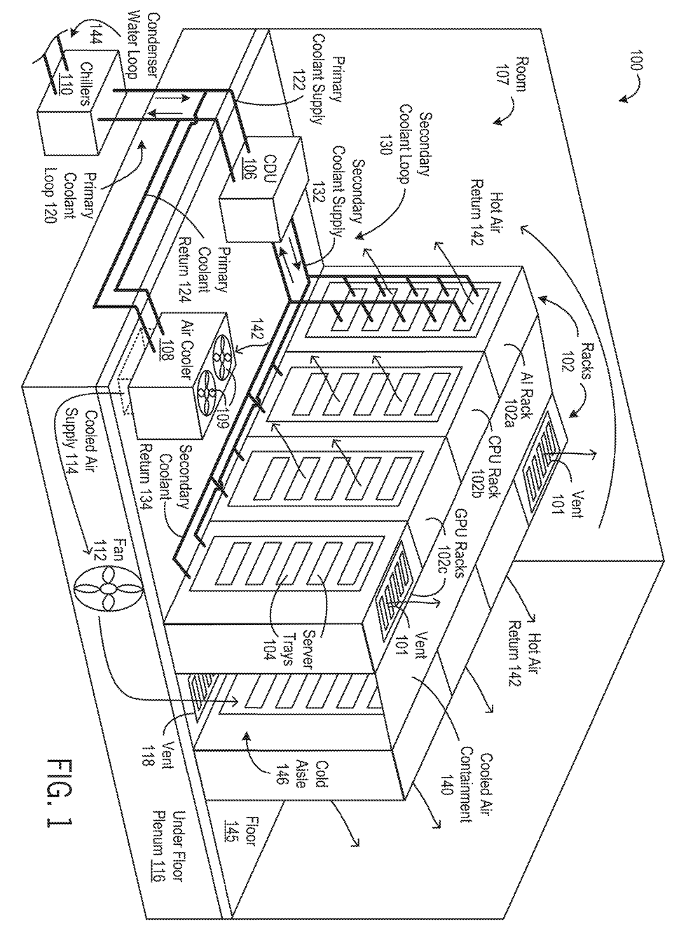

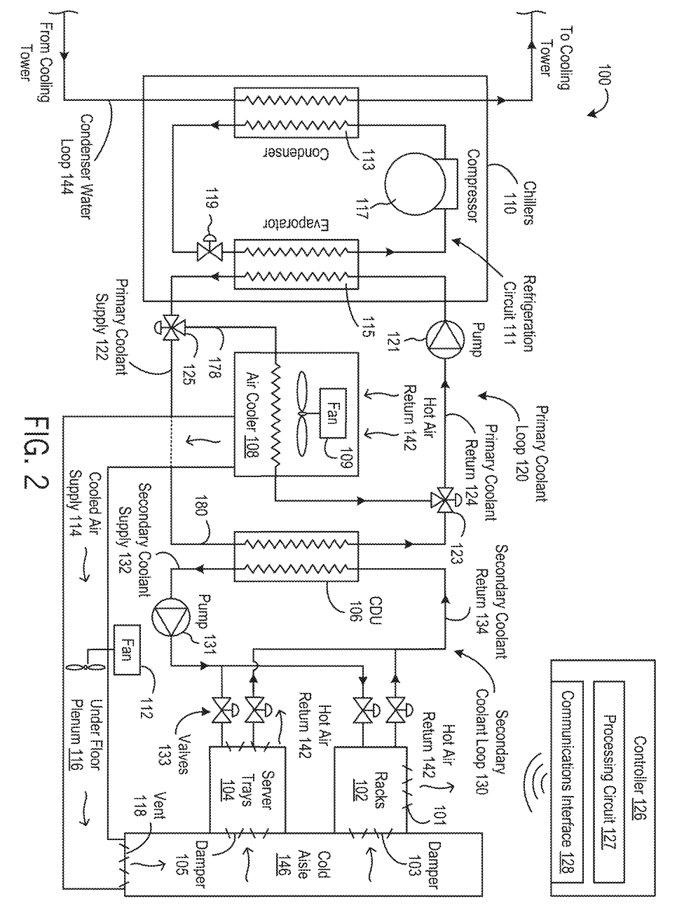

Referring now to FIGS. 1 and 2, a data center cooling system 100 (e.g., computer cooling system) is shown, according to an exemplary embodiment. FIG. 1 is a perspective view of a data center room 107 served by data center cooling system 100, whereas FIG. 2 is a block diagram of data center cooling system 100. Data center room 107 is shown to include several racks 102 (e.g., cabinets, server racks), such as racks 102a, 102b, and 102c (e.g., collectively racks 102) containing server trays 104 (e.g., server blades, server boxes, computer enclosures, other computing devices, etc.). Racks 102 may be arranged in rows (e.g., side-to-side) to form aisles between adjacent rows of racks 102. In some embodiments, the aisles form an alternating sequence of cold aisles and hot aisles on opposite sides of racks 102. For example, the space between the two rows of racks 102 in FIG. 1 is shown as a cold aisle 146 which provides a cooled air supply 114 to racks 102. Cold aisle 146 may be bounded on opposite sides by racks 102, on the bottom by floor 145 (i.e., the floor of data center room 107), and on the top by a cooled air containment 140 (e.g., a solid surface) to contain cooled air supply 114 within cold aisle 146. In some embodiments, cooled air containment 140 also extends vertically along the ends of cold aisle 146 to form a wall perpendicular to both the top surface of cooled air containment 140 and the front and rear surfaces of racks 102 (i.e., the surfaces on which server trays 104 are visible) to prevent cooled air supply 114 from escaping cold aisle 146 via the ends.

In some embodiments, the adjacent rows of racks 102 are arranged front-to-front (i.e., such that the front surfaces of adjacent rows of racks 102 face each other) and back-to-back (i.e., such that the rear surfaces of adjacent rows of racks 102 face each other). For example, as shown in FIG. 1, cold aisle 146 is located between the rear surfaces of adjacent rows of racks 102, whereas the front surfaces of racks 102 face toward hot aisles. In some embodiments, a vent 118 is located along floor 145 of cold aisle 146 to allow cooled air supply 114 to flow into cold aisle 146 from an under floor plenum 116. Racks 102 may draw or receive cooled air supply 114 into racks 102 from cold aisle 146 and pass cooled air supply 114 over heat-producing data center equipment contained within racks 102 (e.g., CPUs, GPUs, dual inline memory modules (DIMMs), servers, power supplies, etc.) which transfer heat to cooled air supply 114. The heated airflow then exits racks 102 through the front surfaces of racks 102 (i.e., the surfaces opposite cold aisle 146) and/or through the top surfaces of racks 102 via vents 101. The heated airflow exiting racks 102 then flows into data center room 107 as a hot air return 142.

In some embodiments, racks 102 can be designated as a particular type based on the type of computing devices they contain (e.g., CPUs, GPUs, DIMMs, ASICs, etc.) and/or based on the type of computing application they run during operation (e.g. AI applications, high performance computing applications, standard computing applications, etc.). For example, rack 102a is shown as an AI rack, rack 102b is shown as a CPU rack, and racks 102c are shown as GPU racks. Similarly, server trays 104 can be designated as AI server trays, CPU server trays, or GPU server trays based on the type of computing devices within server trays 104 and/or the type of computing applications by server trays 104. In some embodiments, data center cooling system 100 uses the type of racks 102 and/or server trays 104 to determine the amount of cooling to provide to each of racks 102 and/or server trays 104. For example, AI rack 102a and GPU racks 102c may require a higher amount of cooling whereas CPU rack 102b may require a lower amount of cooling. Similarly, AI server trays and GPU server trays may require a higher amount of cooling whereas CPU server trays may require a lower amount of cooling.

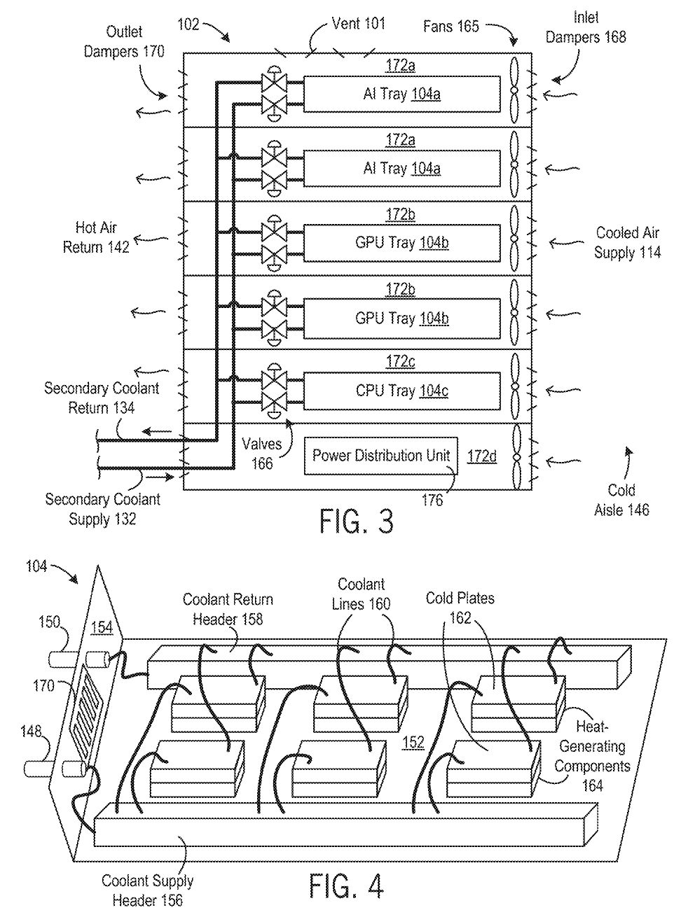

In various embodiments, racks 102 may include top vents 101 located on the top surfaces of racks 102, front vents aligned with each of server trays 104 on the front surfaces of racks 102, or a combination of top vents 101 and front vents. In some embodiments, one or more of racks 102 includes a top vent 101, whereas one or more other racks 102 include front vents. In racks 102 with top vents 101, some or all of the internal volume within such racks 102 may by fluidly connected to allow some or all of the airflow through such racks 102 to exit racks 102 via top vents 101. In racks 102 with front vents aligned with server trays 104, some or all of the internal volume within racks 102 may be portioned into separate compartments within which one or more of server trays 104 are contained. Each compartment may receive a separate airflow stream to provide targeted cooling to the heat-generating equipment contained within the corresponding compartment. One example of how racks 102 can be partitioned into isolated compartments is described in greater detail with reference to FIG. 3. Although only one of GPU racks 102c is shown with top vents 101 in FIG. 1, it is contemplated that any number or type of racks 102 can include top vents 101 and/or or front vents regardless of the type of rack 102. For example, any of AI rack 102a, CPU rack 102b, and/or GPU racks 102c can include front vents and/or top vents 101 in various embodiments.

Still referring to FIGS. 1 and 2, data center cooling system 100 is shown to include air cooling equipment (shown in subsequent figures as air cooling system 230) which provides air cooling to racks 102. The air cooling equipment are shown to include an air cooler 108 and fans 109 and 112 which operate to circulate airflow between air cooler 108 and racks 102. Fan 109 may be positioned to move hot air return 142 from data center room 107 into and through air cooler 108. Air cooler 108 may include any of a variety of airside HVAC equipment configured to provide cooling to hot air return 142 and/or generate cooled air supply 114. For example, air cooler 108 may include one or more computer room air conditioner (CRAC) units, computer room air handler (CRAH) units, direct evaporative cooling (DEC) units, indirect evaporative cooling (IEC) units, free cooling units (e.g., airside economizers), or any other type of airside HVAC equipment. Air cooler 108 may include one or more heat exchangers configured to absorb heat from hot air return 142 to generate cooled air supply 114. In various embodiments, air cooler 108 can be configured to provide mechanical cooling, free cooling, or a combination of mechanical cooling and free cooling to generate cooled air supply 114. For example, air cooler 108 can include any combination of mechanical cooling and free cooling components, as described U.S. Patent No. 9,982,903 granted May 29, 2018, the entire disclosure of which is incorporated by reference herein. Fan 109 can be operated to adjust the airflow rate of cooled air supply 114 and/or the amount of cooling provided to hot air return 142 to generate cooled air supply 114 by controlling the rate at which the airflow passes through air cooler 108.

In some embodiments, air cooler 108 generates cooled air supply 114 by removing heat from hot air return 142. For example, as shown in FIG. 2, air cooler 108 may include an internal heat exchanger (e.g., an air-to-liquid heat exchanger, a cooling coil, etc.) configured to transfer heat from the airflow passing through air cooler 108 into a primary coolant circulating through air cooler 108 via the heat exchanger. In some embodiments, air cooler 108 is configured to generate cooled air supply 114 by exhausting hot air return 142 (e.g., outdoors or into another space other than data center room 107) and drawing cool air into air cooler 108 (e.g., from outdoors or another space) to replace the exhausted hot air return 142. For example, air cooler 108 may operate as an airside economizer configured to provide free cooling to data center room 107 and/or racks 102 when outdoor temperature conditions permit the use of outdoor air. In various embodiments, air cooler 108 may generate cooled air supply 114 by mechanical cooling (e.g., removing heat from hot air return 142), by free cooling (e.g., replacing some or all of hot air return 142 with cooler outdoor air), or by using a combination of mechanical cooling and free cooling.

Air cooler 108 may deliver cooled air supply 114 into under floor plenum 116 which occupies a space below floor 145 of data center room 107. Fan 112 may be located within under floor plenum 116 and configured to move cooled air supply 114 through under floor plenum 116 and into cold aisle 146 via vent 118. Fan 112 can be operated to control the flow rate of cooled air supply 114 through under floor plenum 116 and into cold aisle 146. In some embodiments, data center cooling system 100 may include dampers 103 positioned at the air inlets of racks 102 (e.g., between racks 102 and cold aisle 146 as shown in FIG. 2). Dampers 103 can be operated to modulate the amount of airflow into each of racks 102 individually. Similarly, data center cooling system 100 may include dampers 105 positioned at the air inlets of server trays 104 (e.g., between server trays 104 and cold aisle 146 as shown in FIG. 2). In some embodiments, dampers 103 are used for racks 102 in which some or all of the internal volume is fluidly connected such that the amount of airflow into each rack 102 is controllable at the rack level. Conversely, dampers 105 may be used for racks 102 which are subdivided into compartments to control the airflow through each compartment individually. Although dampers 103 and 105 are shown at the inlets of racks 102 and server trays 104 respectively in FIG. 2, it is contemplated that dampers 103 and dampers 105 may be located at the outlets of racks 102 and server trays 104 or otherwise positioned within racks 102 to control the amount of airflow through each of racks 102 and/or compartments of racks 102.

Still referring to FIGS. 1 and 2, data center cooling system 100 is shown to include liquid cooling equipment (shown in subsequent figures as liquid cooling system 220) which provides liquid cooling to racks 102. The liquid cooling equipment are shown to include a coolant distribution unit (CDU) 106, chillers 110 (e.g., heating, ventilation, air conditioning, and/or refrigeration (HVAC&R) equipment), a primary coolant loop 120, a secondary coolant loop 130, and a condenser water loop 144. Chillers 110 may be configured to provide cooling to a primary coolant (e.g., water, glycol, CO2, ammonia, etc.) which circulates between chillers 110, air cooler 108, and CDU 106 via primary coolant loop 120. As shown in FIG. 2, chillers 110 may include an internal refrigeration circuit 111 (e.g., working fluid circuit, vapor compression circuit) including a compressor 117, a condenser 113, an expansion valve 119, and an evaporator 115. Compressor 117 can be configured to circulate a refrigerant between condenser 113 and evaporator 115 via refrigeration circuit 111. Compressor 117 operates to compress the refrigerant to a high pressure, high temperature state. The compressed refrigerant flows through condenser 113, which transfers heat from the refrigerant in refrigeration circuit 111 to the water in condenser water loop 144. The cooled refrigerant then flows through expansion valve 119, which expands the refrigerant to a low temperature, low pressure state. The expanded refrigerant flows through evaporator 115, which transfers heat from the primary coolant in primary coolant loop 120 to the refrigerant in refrigeration circuit 111. In some embodiments, condenser water loop 144 circulates water or another coolant between condenser 113 and a cooling tower or other location (e.g., another heat exchanger) where the water rejects heat before returning to condenser 113.

In various embodiments, primary coolant loop 120 circulates the primary coolant between chillers 110 and one or both of CDU 106 and air cooler 108. Primary coolant loop 120 may include a pump 121 configured to circulate the primary coolant within primary coolant loop 120. Pump 121 can be operated to control the flow rate of the primary coolant within primary coolant loop 120. In some embodiments, primary coolant loop 120 includes one or more valves 123 and 125 configured to control the flow of the primary coolant through branches 178 and 180 of primary coolant loop 120. Branch 180 may pass through CDU 106, whereas branch 178 may pass through air cooler 108. In some embodiments, as shown in FIG. 2, valves 123 and 125 may be three-way valves positioned at the intersections of branches 178 and 180 (i.e., the location at which primary coolant loop 120 splits into branches 178 and 180) and can be operated to control the flow of the primary coolant supply 122 from chillers 110 to CDU 106 and/or to air cooler 108. Alternatively, valves 123 and 125 can be two-way valves having a single inlet and a single outlet (e.g., on/off valves, adjustable valves, modulating valves, etc.) located along each branch 178 and 180 of primary coolant loop 120 such that valves 123 and 125 can be operated to control the flow of the primary coolant to each of air cooler 108 and CDU 106 individually. In various embodiments, such two-way valves can be located between the intersections shown in FIG. 2 and air cooler 108 (e.g., upstream and/or downstream of air cooler 108), between the intersections shown in FIG. 2 and CDU 106 (e.g., upstream and/or downstream of CDU 106), or otherwise positioned along branches 178 and 180 to selectively control the flow rate of primary coolant supply 122 along each of branches 178 and 180.

The liquid coolant in primary coolant loop 120 is cooled by chillers 110 in evaporator 115 to generate primary coolant supply 122. Although only one evaporator 115 is shown in FIG. 2 for ease of illustration, it is contemplated that primary coolant loop 120 may include one or more evaporators 115 arranged in parallel (e.g., parts of parallel chillers 110) or in series (e.g., parts of series chillers 110) to provide cooling to the liquid coolant circulating in primary coolant loop 120. Primary coolant supply 122 flows through primary coolant loop 120 into branch 178 which passes through air cooler 108 and/or branch 180 which passes through CDU 106. The primary coolant absorbs heat from hot air return 142 in air cooler 108 and/or from the secondary coolant in CDU 106 to generate primary coolant return 124. Primary coolant return 124 then returns from air cooler 108 and/or CDU 106 to chillers 110 to be cooled once again and the cycle repeats.

In various embodiments, the liquid coolant circulating in primary coolant loop 120 can be cooled using any combination of mechanical cooling and/or free cooling. For example, in one embodiment a first portion (e.g., a first branch) of primary coolant loop 120 may pass through chillers 110 to receive mechanical cooling from chillers 110, whereas a second portion (e.g., a second branch) of primary coolant loop 120 may pass through one or more free cooling devices (e.g., outdoor air heat exchangers, cooling towers, etc.) to receive free cooling when outdoor temperature conditions permit using free cooling. Several examples of how a hybrid mechanical cooling and free cooling system can be constructed are described in detail in U.S. Patent No. 9,982,903 incorporated by reference above.

In some embodiments, data center cooling system 100 includes multiple primary coolant loops 120 configured to circulate the primary coolant at different temperatures. For example, a first primary coolant loop 120 may be configured to circulate a relatively higher temperature coolant, a second primary coolant loop 120 may be configured to circulate relatively colder temperature coolant, and a third primary coolant loop 120 may be configured to circulate coolant at a medium temperature between the relatively higher and lower temperatures.

CDU 106 can be configured to transfer heat between the primary coolant in primary coolant loop 120 and the secondary coolant (e.g., water, glycol, CO2, ammonia, etc.) in secondary coolant loop 130. It is expected that the secondary coolant in secondary coolant loop 130 is warmer than the primary coolant in primary coolant loop 120 and thus the direction of heat transfer within CDU 106 is from the secondary coolant to the primary coolant (i.e., from secondary coolant loop 130 to primary coolant loop 120). In various embodiments, the primary coolant and the secondary coolant may be the same or different coolants and may be kept fluidly separate from each other by containing them within their respective coolant loops 120 and 130. CDU 106 is shown as a heat exchanger (e.g., a liquid-to-liquid heat exchanger, a heat exchange coil, etc.) which receives primary coolant supply 122 from primary coolant loop 120 and secondary coolant return 134 from secondary coolant loop 130. CDU 106 may transfer heat from the relatively warmer secondary coolant return 134 into the relatively colder primary coolant supply 122 to provide cooling to the secondary coolant and generate secondary coolant supply 132.

Secondary coolant loop 130 can be configured to circulate the secondary coolant between CDU 106 and one or both of racks 102 and server trays 104. Secondary coolant loop 130 may include a pump 131 configured to circulate the secondary coolant within secondary coolant loop 130. Pump 131 can be operated to control the flow rate of the secondary coolant within secondary coolant loop 130 and/or the rate of heat transfer between the primary coolant and the secondary coolant in CDU 106. In some embodiments, secondary coolant loop 130 includes one or more valves 133 configured to control the flow of the secondary coolant through racks 102 and/or server trays 104. In various embodiments, valves 133 may be located at the coolant inlets of racks 102 or server trays 104 and/or at the coolant outlets of racks 102 or server trays 104 to control the flow of the secondary coolant through each of racks 102 and/or server trays 104 individually. Although valves 133 are shown at both the inlets and outlets of racks 102 and server trays 104 in FIG. 2, it is contemplated that such an arrangement may be redundant and that a single valve located at either the inlet or the outlet of each of racks 102 or server trays 104 may be sufficient to control the flow of the secondary coolant through each of racks 102 and server trays 104 individually.

In some embodiments, secondary coolant loop 130 provides the secondary coolant to one or more of racks 102 in parallel. For example, as shown in FIG. 1, the three racks 102b and 102c are shown receiving secondary coolant supply 132 from secondary coolant loop 130 and discharging secondary coolant return 134 as an output of racks 102. Such racks 102b and 102c may have internal valves (e.g., valves 166 shown in FIG. 3), pumps, or other flow control devices which can be operated to independently control the flow of secondary coolant supply 132 to each of server trays 104 and/or individual heat-generating components 164 located within racks 102b and 102c, as described in greater detail with reference to FIGS. 3 and 4. In some embodiments, secondary coolant loop 130 provides the secondary coolant directly to one or more of server trays 104 in parallel. For example, as shown in FIG. 1, rack 102a is shown with secondary coolant supply 132 being delivered to each of server trays 104 of rack 102a in parallel. In various embodiments, secondary coolant loop 130 can deliver the secondary coolant to one or more of racks 102 and/or one or more of server trays 104 in parallel.

Although server trays 104 are shown separate from racks 102 in FIG. 2, it is understood that server trays 104 may be installed within racks 102 and thus may be considered components of racks 102 in some embodiments. The separate depiction of racks 102 and server trays 104 in FIG. 2 is intended to illustrate that the air cooling system (e.g., air cooler 108, fans 109 and 112, dampers 103 and 105, etc.) may provide cooled air supply 114 directly to one or more of server trays 104 (e.g., directly from cold aisle 146) without first requiring cooled air supply 114 to enter the racks 102 within which such server trays 104 are contained. For example, one or more of server trays 104 may have a cooled air intake located along an edge or surface of racks 102 adjacent to cold aisle 146 and configured to receive cooled air supply 114 directly from cold aisle 146 (e.g., via dampers 105). Accordingly, the amount of cooling provided to each of server trays 104 by the air cooling system can be independently adjusted by controlling the airflow rate of cooled supply air 114 and/or the temperature of cooled supply air 114 provided to each of server trays 104 individually. Other server trays 104 may be located within a shared volume within racks 102 and configured to receive cooled air supply 114 after cooled air supply 114 enters racks 102. For example, racks 102 may include dampers 103 which can be operated to control the flow rate of cooled air supply 114 into each of racks 102 individually. In racks 102 with a single large compartment containing multiple server trays 104, cooled air supply 114 may pass across or through multiple server trays 104 within a given rack 102 after entering the rack 102 (e.g., via dampers 103).

Although AI rack 102a is the only type of racks 102 shown in FIG. 1 as receiving the secondary coolant directly from secondary coolant loop 130 to each of server trays 104 within rack 102a, it is contemplated that any of racks 102 can be connected to secondary coolant loop 130 at the server tray level (i.e., with a separate coolant inlet and outlet for each of server trays 104 within the rack) and that such connectivity is not limited to racks 102 designated as AI racks. For example, any of CPU rack 102b and/or GPU racks 102c can also or alternatively be connected to secondary coolant loop 130 at the server tray level in various embodiments. Similarly, while CPU rack 102b and GPU racks 102c are the only type of racks 102 shown in FIG. 1 with a single coolant inlet and single coolant outlet connecting to secondary coolant loop 130, it is contemplated that any of racks 102 can be connected to secondary coolant loop 130 at the rack level (i.e., with a single coolant inlet and outlet for the rack as a whole) and that such connectivity is not limited to racks designated as CPU racks or GPU racks. For example, AI rack 102a can also or alternatively be connected to secondary coolant loop 130 at the rack level in some embodiments.

In some embodiments, primary coolant loop 120 and/or secondary coolant loop 130 supply a liquid coolant (e.g., water, glycol, etc.) to racks 102, server trays 104, and/or to individual heat-generating components installed on server trays 104 (e.g., CPUs, GPUs, etc.) to provide targeted cooling to such components. However, it is contemplated that data center cooling system 100 is not limited to using liquid coolants in primary coolant loop 120 and/or secondary coolant loop 130, but rather can use any of a variety of fluid coolants in various embodiments (e.g., gas coolants, liquid coolants, vapor coolants, mixed phase (liquid/vapor, liquid/gas) coolants, and/or any other type of fluid coolant). Accordingly, it should be understood that all references to liquid coolants throughout the present disclosure including the claims presented herein can be replaced with any other type of fluid coolant without departing from the teachings of the present disclosure.

Referring now to FIG. 3, one of racks 102 is shown in greater detail, according to an exemplary embodiment. Rack 102 is shown to include several compartments 172a, 172b, 172c, and 172d (collectively compartments 172) containing different types of server trays 104 and a power distribution unit (PDU) 176. In particular, compartments 172a are shown containing AI trays 104a, compartments 172b are shown containing GPU trays 104b, compartment 172c is shown containing CPU tray 104c, and compartment 172d is shown containing PDU 176. As noted above, the types of server trays 104 within compartments 172 may correspond to the types of computing applications run by server trays 104 and/or the types of computing devices located on server trays 104 (e.g., AI applications, high performance computing applications, GPUs, CPUs, DIMMS, etc.).

In some embodiments, compartments 172 are fluidly isolated from each other (e.g., by solid surfaces within racks 102 forming upper and lower boundaries of compartments 172) such that the airflow streams through compartments 172 do not mix with each other within racks 102. Accordingly, each of compartments 172 may receive a separate stream of cooled air supply 114 from cold aisle 146 for use in cooling the heat-producing data center equipment therein. The streams of cooled air supply 114 may be kept separate from each other within racks 102 such that each stream of cooled air supply 114 cools a corresponding compartment 172. In other embodiments, racks 102 may not include compartments 172 (or one or more of compartments 172 may be joined into a larger compartment) such that some or all of the internal volume within racks 102 is fluidly connected. In such an embodiment, racks 102 may receive one or more streams of cooled air supply 114 from cold aisle 146 and may allow the streams of cooled air supply 114 to mix or join within racks 102.

In some embodiments, racks 102 include inlet dampers 168 positioned at the cold air intake of racks 102 (e.g., between cold aisle 146 and compartments 172). Inlet dampers 168 may be aligned with compartments 172 and individually operated to independently control the flow of cooled air supply 114 into and through each of compartments 172. Dampers 103 and 105 shown in FIG. 2 may be types of inlet dampers 168 shown in FIG. 3. Similarly, racks 102 may include inlet dampers 168 positioned at the hot air exhaust of racks 102 (e.g., between compartments 172 and the hot aisle or data center room 107). Outlet dampers 170 may be aligned with compartments 172 and individually operated to independently control the flow of cooled air supply 114 out of and through each of compartments 172. Although compartments 172 are shown equipped with both inlet dampers 168 and outlet dampers 170 in FIG. 3, it is contemplated that such an arrangement may be redundant and that only one of inlet dampers 168 or outlet dampers 170 may be installed and used to control the airflow through each of compartments 172 in some embodiments. Alternatively, both inlet dampers 168 and outlet dampers 170 may be installed and used to control the airflow through compartments 172 in some embodiments.

In some embodiments, cooled air supply 114 within cold aisle 146 is maintained at an air pressure above the air pressure within data center room 107 such that the pressure differential causes cooled air supply 114 to flow through compartments 172 when inlet dampers 168 and/or outlet dampers 170 are open. For example, air cooler 108 and/or fan 112 may be operated to maintain cold aisle 146 at a positive air pressure relative to the air pressure within data center room 107. In some embodiments, racks 102 include fans 165 positioned within each compartment 172 (e.g., upstream or downstream of server trays 104). Fans 165 can be operated to independently control the flow rate of cooled air supply 114 through each of compartments 172 to provide different air flow rates to different server trays 104 within a given rack 102.

For racks 102 that contain multiple compartments 172, each compartment 172 may be equipped with an inlet damper 168, outlet damper 170, and/or fan 165. These components can be operated to independently control the flow rate of cooled air supply 114 through each compartment 172, and thus modulate the amount of cooling provided to each of server trays 104 by cooled air supply 114. For racks 102 that do not contain multiple compartments 172, such racks 102 may include one or more of inlet dampers 168, outlet dampers 170, and/or fans 165 which can be operated to control the flow rate of cooled air supply 114 through the rack 102 as a whole. In this way, each rack 102 can be provided with a different amount of air cooling either at the rack level or at the server tray level. In some embodiments, inlet dampers 168 and/or outlet dampers 170 can be replaced with vents or held permanently open to provide the same functionality as a vent. In such embodiments, airflow through each of compartments 172 can be controlled by operating fans 165 and/or by controlling the air pressure within cold aisle 146.

Still referring to FIG. 3, rack 102 is shown to include valves 166. Valves 166 may be located along secondary coolant loop 130 and operated to control the flow of the secondary coolant through rack 102 and/or server trays 104. In various embodiments, valves 166 can be located along secondary coolant supply 132 (e.g., upstream of server trays 104), along secondary coolant return 134 (e.g., downstream of server trays 104), or in both locations as shown in FIG. 3. However, it is contemplated that positioning valves 166 both upstream and downstream of server trays 104 may be redundant and that only one of an upstream valve 166 or a downstream valve 166 may be required to control the flow of the secondary coolant through rack 102 and/or server trays 104. In some embodiments, rack 102 includes one or more valves 166 within each of compartments 172 or otherwise positioned to control the flow of the secondary coolant to each of server trays 104 individually. Such an arrangement allows each of server trays 104 to receive a different flow rate of the secondary coolant from secondary coolant supply 132 (e.g., by operating valves 166) to modulate the amount of liquid cooling provided to each of server trays 104 independently. Although not explicitly shown in FIG. 3, it is contemplated that PDU 176 may also be cooled by secondary coolant loop 130 and may receive a flow of secondary coolant supply 132 in some embodiments.

In some embodiments, valves 166 and/or valves 133 can be operated to open or close different branches of secondary coolant loop 130. For example, valves 133 shown in FIG. 2 can be closed to prevent the secondary coolant from flowing into and through one or more of racks 102 or server trays 104 connected in series with valves 133 or opened to allow the secondary coolant to flow through into and through one or more of racks 102 or server trays 104 connected in series with valves 133. Similarly, valves 166 shown in FIG. 3 can be opened or closed to allow the secondary coolant to flow through individual server trays 104 within a given rack 102 while preventing the secondary coolant from flowing through other server trays 104 within a given rack 102. Valves 166 and 133 can be modulated between fully open positions and fully closed positions (i.e., set to any position between and including fully open and fully closed) to selectively control the amount of proportion of the secondary coolant that flows through each of racks 102 and/or server trays 104. In this way, the flow of the secondary coolant can be controlled (e.g., increased, decreased, etc.) or cut-off entirely to some or all of racks 102 or server trays 104 based on their individual cooling requirements. In some embodiments, valves 166 and 133 can be closed to allow some racks 102 or server trays 104 to be disconnected from secondary coolant loop 130 (e.g., for maintenance, replacement, etc.). Valves 166 and 133 can also or alternatively be closed to increase the efficiency of pump 131 by preventing pressure losses within secondary coolant loop 130 caused by pumping the secondary coolant through racks 102 or server trays 104 that do not require liquid cooling.

Referring now to FIG. 4, one of server trays 104 is shown in greater detail, according to an exemplary embodiment. Server tray 104 is shown to include a surface 152 (e.g., a bottom surface, a board, a substrate, etc.) on which one or more heat-generating components 164 are mounted or installed. Heat-generating components 164 may include any type of computing device or other data center component that generates heat during operation (e.g., CPUs, GPUs, ASICs, DIMMs, power supplies, etc.). Server tray 104 is shown to include cold plates 162 thermally coupled to heat-generating components 164 (e.g., positioned on or near heat-generating components 164 to facilitate heat transfer between cold plates 162 and heat-generating components 164) and configured to absorb heat from heat-generating components 164 during operation. Cold plates 162 may include heat sinks, tubes, liquid-to-solid heat exchangers, or any other structure configured to draw heat away from heat-generating components 164. Cold plates 162 may receive flows of the secondary coolant from secondary coolant loop 130 and transfer heat from heat-generating components 164 into the secondary coolant.

Server tray 104 is shown to include a front surface 154 having a coolant inlet port 148 and a coolant outlet port 150. Coolant inlet port 148 may be connected to secondary coolant supply 132 and may receive a flow of the chilled secondary coolant from secondary coolant loop 130. The chilled secondary coolant may flow from coolant inlet port 148 into a coolant supply header 156. Coolant supply header 156 may be connected to each of cold plates 162 via coolant lines 160 and may deliver the chilled secondary coolant to cold plates 162. The secondary coolant absorbs heat from cold plates 162 and thus provides cooling to heat-generating components 164 thermally coupled to cold plates 162. The warmed secondary coolant then flows from cold plates 162 into coolant return header 158 via coolant lines 160. Coolant return header 158 may be fluidly coupled with coolant outlet port 150 and configured to discharge the warmed secondary coolant back to secondary coolant loop 130 via coolant outlet port 150.

In some embodiments, cold plates 162 also or alternatively include fins, plates, solid-to-air heat exchangers, or other structures configured to transfer heat from cold plates 162 into cooled air supply 114 flowing across server tray 104. Cooled air supply 114 may flow across server tray 104 and absorb heat from heat-generating components 164 either directly or via cold plates 162. The warmed airflow may then exit server tray 104 via front surface 154 through outlet damper 170 and/or a front vent in various embodiments.

Referring generally to FIGS. 1-4, data center cooling system 100 may include a variety of sensors (e.g., temperature sensors, flow rate sensors, pressure sensors, etc.) positioned to measure the temperatures, flow rates, pressures, or other conditions of the airflow and liquid coolant at various locations within data center cooling system 100. For example, data center cooling system 100 may include air sensors positioned at the inlet or outlet of air cooler 108 (e.g., upstream or downstream of the heat exchanger within air cooler 108), within under-floor plenum 166, at the air inlet or outlet of each rack 102 (e.g., upstream or downstream of server trays 104), at the air inlet or outlet of each of compartments 172 (e.g., proximate to inlet dampers 168 or outlet dampers 170), within compartments 172, within data center room 107, or otherwise within the data center to measure the temperatures, flow rates, pressures, and/or other conditions of the airflow at the locations of the air sensors. For example, data center cooling system 100 may include flow rate sensors and/or temperature sensors configured to measure the flow rate or temperature of cooled air supply 114 entering each of racks 102 or each of compartments 172 and/or the flow rate or temperature of hot air return 142 exiting each of racks 102 or each of compartments 172 independently.

Data center cooling system 100 may include liquid coolant or refrigerant sensors positioned at the coolant inlets or outlets of chillers 110 (e.g., along primary coolant loop 120 upstream or downstream of evaporator 115), at any location within refrigeration circuit 111, at the coolant inlets or outlets of CDU 106 (e.g., along primary coolant loop 120 upstream or downstream of CDU 106, along secondary coolant loop 130 upstream or downstream of CDU 106), at the inlets or outlets of individual racks 102 or server trays 104 (e.g., along secondary coolant supply 132 or secondary coolant return 134), or immediately upstream or downstream of individual heat-generating components 164 within server trays 104 to measure the temperatures, flow rates, pressures, and/or other conditions of the liquid coolant or refrigerant at the locations of the liquid coolant or refrigerant sensors. For example, data center cooling system 100 may include flow rate, pressure, or temperature sensors configured to measure the flow rate, pressure, or temperature of the primary coolant entering or exiting chillers 110 (e.g., position upstream or downstream of chillers 110 along primary coolant loop 120), the secondary coolant entering or exiting CDU 106 (e.g., along secondary coolant loop 130 upstream or downstream of CDU 106), the secondary coolant entering or exiting racks 102 or server trays 104 (e.g., along secondary coolant loop 130 upstream or downstream or racks 102 or server trays 104), the refrigerant in refrigeration circuit 111 (e.g., between any of condenser 113, expansion valve 119, evaporator 115, and compressor 117), along condenser water loop 144 upstream or downstream of chillers 110, or otherwise positioned to measure any variable state or condition of the refrigerant, primary coolant, secondary coolant, or condenser water at any location in data center cooling system 100.

In some embodiments, data center cooling system 100 includes temperature sensors configured to measure the temperatures of heat-generating components 164 (e.g., CPU temperatures, GPU temperatures, etc.). Such temperature sensors may be integrated with heat-generating components 164 (e.g., internal thermocouples or other built-in temperature sensors) or additional components of data center cooling system 100 installed to measure the temperatures at or near each of heat-generating components 164. In some embodiments, data center cooling system 100 includes power sensors configured to measure the amount of power delivered to each of racks 102, server trays 104, heat-generating components 164, or other computing devices within the data center. In some embodiments, the power sensors are implemented as wattage sensors, current sensors, or voltage sensors configured to measure the amount of electric power delivered to various components of the data center or measure variables from which power can be derived (e.g., voltage, current, etc.).

Referring particularly to FIG. 2, data center cooling system 100 is shown to include a controller 126. Controller 126 is shown to include a processing circuit 127 and a communications interface 128. Processing circuit 127 may include one or more processors and memory. The processors (shown in subsequent figures as processor 222) may include one or more general purpose or specific purpose processors, application specific integrated circuits (ASIC), one or more field programmable gate arrays (FPGAs), a group of processing components, or other suitable processing components. The processors may be configured to execute computer code or instructions stored in the memory or received from other computer readable media (e.g., CDROM, network storage, a remote server, etc.). The memory (shown in subsequent figures as memory 223) may include one or more devices (e.g., memory units, memory devices, storage devices, etc.) for storing data and/or computer code for completing and/or facilitating the various processes described in the present disclosure. The memory may include random access memory (RAM), read-only memory (ROM), hard drive storage, temporary storage, non-volatile memory, flash memory, optical memory, or any other suitable memory for storing software objects and/or computer instructions. The memory may include database components, object code components, script components, or any other type of information structure for supporting the various activities and information structures described in the present disclosure. The memory may be communicably connected to the processors via processing circuit 127 and may include computer code for executing (e.g., by the processors) one or more processes described herein.

Communications interface 128 may include wired or wireless interfaces (e.g., jacks, antennas, transmitters, receivers, transceivers, wire terminals, etc.) for conducting data communications with various systems, devices, or networks. For example, communications interface 128 may include an Ethernet card and port for sending and receiving data via an Ethernet-based communications network and/or a Wi-Fi transceiver for communicating via a wireless communications network. Communications interface 128 may be configured to communicate via local area networks or wide area networks (e.g., the Internet, a building WAN, etc.) and may use a variety of communications protocols (e.g., BACnet, IP, LON, etc.). Communications interface 128 may be configured to facilitate electronic data communications between controller 126 and various other systems or devices of data center cooling system 100 (e.g., sensors, controllable equipment, etc.) or other external data sources, systems, or devices outside data center cooling system 100. For example, controller 126 may be configured to communicate with any or all of the controllable equipment of data center cooling system 100 (e.g., CDU 106, air cooler 108, fan 109, chillers 110, fan 112, compressor 117, expansion valve 119, pump 121, valve 123, valve 125, valves 133, pump 131, dampers 103, dampers 105, inlet dampers 168, outlet dampers 170, valves 166, fans 165, etc.) and any or all of the sensors in data center cooling system 100 (e.g., any of the temperature sensors, pressure sensors, flow rate sensors, power sensors, etc.).

Controller 126 can be configured to receive measurements from the sensors and operate the controllable equipment of data center cooling system 100 to control the flow rates, pressures, temperatures, or other variable states or conditions of cooled air supply 114, hot air return 142, the refrigerant in refrigeration circuit 111, the condenser water in condenser water loop 144, the primary coolant in primary coolant loop 120, the secondary coolant in secondary coolant loop 130, or any portions thereof. In some embodiments, controller 126 receives reported values of temperatures, power consumption, or other measured or calculated variables from heat-generating components 164, PDU 176, or other data center equipment configured to report their own operating conditions (e.g., temperatures, power consumption, power delivered, computing load, etc.).

Controller 126 can use any of a variety of feedback control processes (e.g., closed-loop control, reset control, etc.), feedforward or predictive control processes (e.g., model predictive control, prediction-based control, etc.), or other control processes to operate the controllable equipment of data center cooling system 100 based on the measured values from installed sensors or reported variables from the data center equipment. Several examples of particular control processes which can be performed by controller 126 are described in detail below. Advantageously, controller 126 can be configured to precisely modulate the amount of cooling provided to each of racks 102, server trays 104, and/or individual heat-generating components 164 (referred to generally as “heat loads”) by both the air cooling equipment and the liquid cooling equipment of data center cooling system 100. Controller 126 can independently adjust the amount of cooling provided individual heat loads within the data center by controlling the air cooling equipment and the liquid cooling equipment that serve each heat load independently. This allows controller 126 to provide targeted cooling to various heat loads as needed without overcooling other heat loads more than necessary to dissipate the amount of heat generated during operation.

In some embodiments, data center cooling system 100 includes some or all of the components, features, or functionality described in U.S. Patent Application No. 17/741,108 filed May 10, 2022, U.S. Patent No. 11,497,144 granted November 8, 2022, U.S. Patent Application No. 18/308,418 filed April 27, 2023, U.S. Patent Application No. 18/308,422 filed April 27, 2023, U.S. Patent Application No. 18/641,658 filed April 22, 2024, Indian Provisional Patent Application No. 202441090506 filed November 2021, 2024, U.S. Provisional Patent Application No. 63/804,615 filed May 12, 2025, U.S. Provisional Patent Application No. 63/804,544 filed May 12, 2025, U.S. Provisional Patent Application No. 63/804,546 filed May 12, 2025, U.S. Provisional Patent Application No. 63/804,553 filed May 12, 2025, and/or U.S. Provisional Patent Application No. 63/804,558 filed May 12, 2025, all of which are incorporated by reference herein in their entireties. For example, controller 126 can be configured to execute any or all of the control processes described in any of the patents, patent applications, or other documents incorporated by reference throughout the present disclosure in the context of data center cooling system 100. Data center cooling system 100 can include any or all of the equipment described in any of the aforementioned documents in various embodiments. In addition to the functionality described in these documents, controller 126 can be configured to execute a variety of new control processes that improve upon the prior art in various ways, several examples of which are described in detail below.

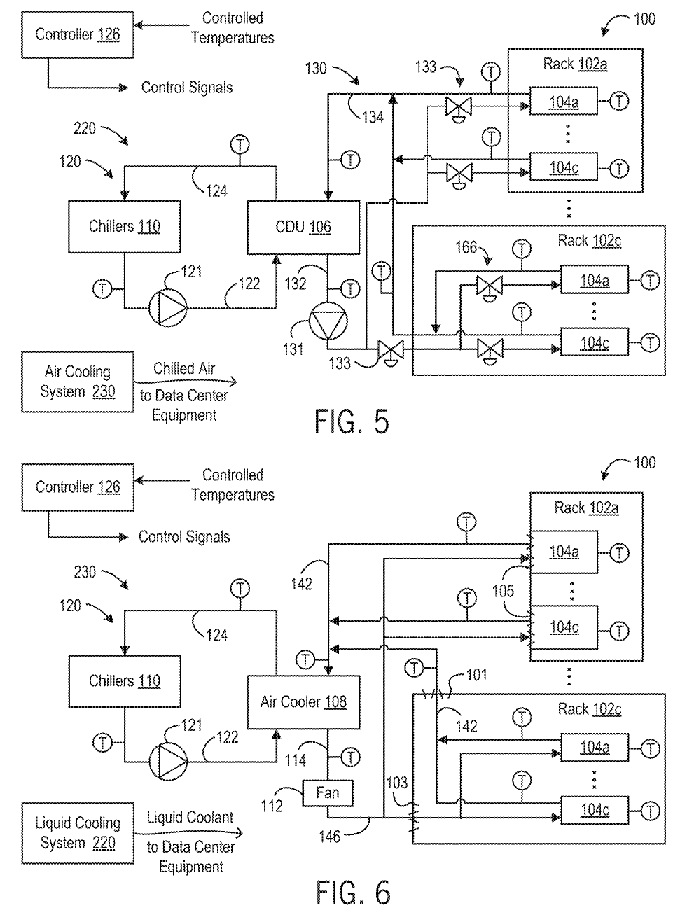

Referring now to FIGS. 5 and 6, data center cooling system 100 is shown in greater detail, according to some embodiments. FIG. 5 illustrates the fluid connections of liquid cooling system 220 including primary coolant loop 120 and secondary coolant loop 130 (referred to herein as liquid cooling loops or liquid cooling circuits). Primary coolant loop 120 circulates a primary coolant between chillers 110 and CDU 106. The primary coolant exits chillers 110 into primary coolant supply 122 and then flows into CDU 106 wherein the primary coolant absorbs heat from the secondary coolant. The primary coolant then exits CDU 106 and flows into primary coolant return 124 after absorbing heat from the secondary coolant in CDU 106. Pump 121 operates to circulate the primary coolant between chillers 110 and CDU 106 and can be located along primary coolant supply 122 and/or primary coolant return 124 in various embodiments. Temperature sensors (shown as circles containing “T” in FIGS. 5 and 6) can be located along primary coolant supply 122 and configured to measure the temperature of the primary coolant exiting chillers 110 or entering CDU 106. Temperature sensors can also or alternatively be located along primary coolant return 124 and configured to measure the temperature of the primary coolant exiting CDU 106 or entering chillers 110.

Secondary coolant loop 130 circulates a secondary coolant between CDU 106, racks 102, and/or server trays 104. The secondary coolant exits CDU 106 after rejecting heat to the primary coolant and flows into secondary coolant supply 132. Valves 133 may be located along secondary coolant supply 132 and can be operated to control the flow of the secondary coolant into each of racks 102 individually. In some embodiments, one or more of racks 102 includes additional valves 166 which can be operated to control the flow of the secondary coolant in to each of server trays 104 individually. Pump 131 operates to circulate the secondary coolant between CDU 106, racks 102, and/or server trays 104 and can be located along secondary coolant supply 132 and/or secondary coolant return 134 in various embodiments. In some embodiments, controller 126 operates CDU 106 to maintain the temperature of the liquid coolant in secondary coolant supply 132 and/or secondary coolant return 134 at or above a dew point temperature of the air within the data center to prevent condensation on liquid lines.

Temperature sensors can be located along any of secondary coolant supply 132 (e.g., at the outlet of CDU 106, at the inlets of racks 102, at the inlets of server trays 104, etc.), secondary coolant return 134 (e.g., at the inlet of CDU 106, at the outlets of racks 102 and/or server trays 104, etc.) and configured to measure the temperature of the secondary coolant at the locations of the temperature sensors. In some embodiments, secondary coolant loop 130 includes a temperature sensor located at the outlet of each of racks 102 and/or server trays 104 and configured to measure the temperatures of the secondary coolant exiting each of racks 102 and/or server trays 104. In some embodiments, data center cooling system 100 includes temperature sensors configured to measure the temperatures of each of racks 102, server trays 104, and/or individual components of data center equipment 240 (e.g., CPU temperatures, GPU temperatures, etc.).

FIG. 6 illustrates the fluid connections of air cooling system 230 including primary coolant loop 120 and an air cooling loop 232. Primary coolant loop 120 may be the same as described with reference to FIG. 5 with the exception that primary coolant loop 120 delivers the primary coolant to air cooler 108. Air cooler 108 transfers heat from the air into the primary coolant to generate cooled air supply 114. Temperature sensors can be located along primary coolant supply 122 and configured to measure the temperature of the primary coolant exiting chillers 110 or entering air cooler 108. Temperature sensors can also or alternatively be located along primary coolant return 124 and configured to measure the temperature of the primary coolant exiting air cooler 108 or entering chillers 110.

Air cooling loop 232 (e.g., an air cooling circuit) circulates air between air cooler 108, racks 102, and/or server trays 104. Cooled air supply 114 exits air cooler 108 and is circulated by fan 112 through cold aisle 146 and into racks 102 via dampers 103 and/or into server trays 104 via dampers 105. Cooled air supply 114 absorbs heat from data center equipment 240 within racks 102 and/or server trays 104 and exits racks 102 and/or server trays 104 via top vents 101 and/or dampers 105. Temperature sensors can be positioned to measure the temperature of the cooled air supply 114 exiting air cooler 108 (e.g., within cold aisle 146, at the inlets of racks 102 and/or server trays 104, etc.), the temperature of the air exiting racks 102 and/or server trays 104 (e.g., immediately downstream of racks 102 and/or server trays 104, at the outlets of racks 102 and/or server trays 104), or any other location within air cooling loop 232. In general, temperature sensors can be located at any of the positions shown in FIGS. 5 and 6 or otherwise located in liquid cooling system 220 and/or air cooling system 230 to measure the temperatures of the primary coolant, secondary coolant, cooled air, or other coolant temperatures at any location within liquid cooling system 220 and/or air cooling system 230.

Some cooling systems implemented with data centers include numerous stages of heat exchange, which may limit an overall efficiency or effectiveness of such cooling systems to transfer and reject heat generated by electronic equipment in data centers. To this end, present embodiments are directed to improved configurations of cooling systems configured to provide cooling to electronic equipment with increased efficiency and effectiveness. For example, certain cooling systems incorporating the techniques described herein include a chiller system having a working fluid circuit configured to circulate a working fluid (e.g., refrigerant) to cool a conditioning fluid (e.g., water, glycol, water and glycol mixture), and a conditioning fluid circuit configured to circulate the conditioning fluid between the chiller system and the electronic equipment. More specifically, the conditioning fluid circuit is configured to place the conditioning fluid in a heat exchange relationship with the working fluid circulated through the working fluid circuit of the chiller system and is also configured to place the conditioning fluid in a heat exchange relationship with the electronic equipment.

In other embodiments, the chiller system may be configured to cool a working fluid and direct the working fluid to the electronic equipment to place the working fluid in a heat exchange relationship with the electronic equipment, such as via a cold plate, a tube, a flow path, a channel, a vessel, and/or immersion cooling techniques. In such embodiments, the cooling system may not include a conditioning fluid circuit configured to place a conditioning fluid in a heat exchange relationship with the electronic equipment. Instead, at least a portion of the working fluid circuit may extend from the chiller system to the electronic equipment, thereby enabling the working fluid to absorb heat from the electronic equipment. Accordingly, certain embodiments discussed herein may not incorporate a CDU that includes a heat exchanger configured to enable heat transfer between two flows of fluid, such as a conditioning fluid cooled by a chiller system and a coolant placed in a heat exchange relationship with electronic equipment. Additionally, certain embodiments discussed herein may not include an evaporator of a chiller system configured to enable heat transfer between a working fluid circulated through the chiller system and a conditioning fluid placed in a heat exchange relationship with the electronic equipment. Therefore, one or more stages of heat transfer typically included in some cooling systems is omitted, which enables enhanced efficiency of the chiller system and increased heat rejection of heat generated by the electronic equipment.

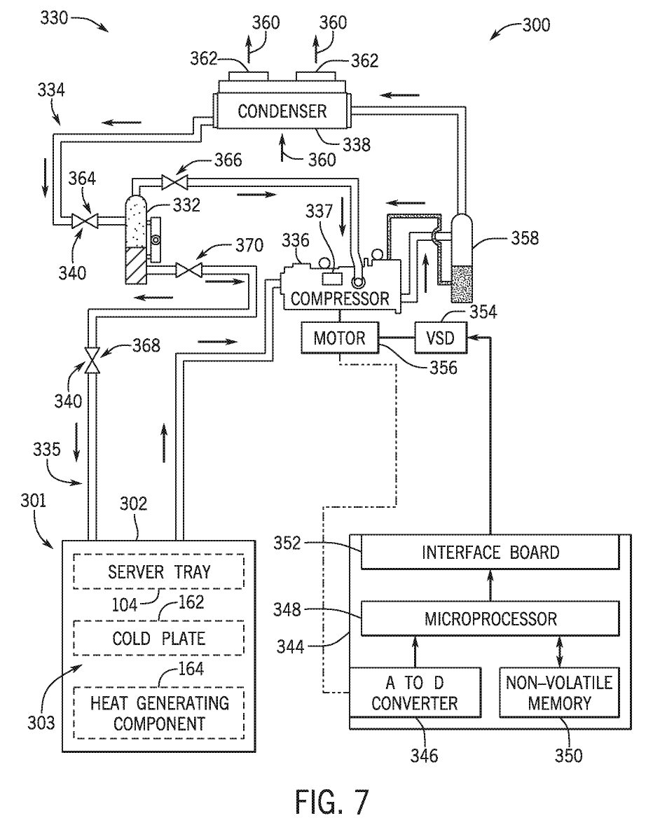

With the preceding in mind, FIG. 7 is a schematic of an embodiment of a cooling system 300 (e.g., computer cooling system, electronic equipment cooling system, data center cooling system) configured to provide cooling to electronic equipment 301. In certain embodiments, the electronic equipment 301 may be an embodiment of a computer enclosure 302 configured to house and/or support computer componentry 303 (e.g., computer components), such as one or more server trays 104, one or more cold plates 162, one or more heat-generating components 164, or any combination thereof. Additionally, or alternatively, the electronic equipment 301 may be an embodiment of a rack or cabinet, such as an embodiment of the rack 102, configured to house and/or support multiple computer enclosures 302, each being configured to house and/or support respective computer componentry 303 (e.g., integrated circuits, circuit boards, communication circuitry, processors, servers, server trays, computer chips, memories, routers, switches, controllers, heat-generating components, and/or other computer hardware).

In the illustrated embodiment, the cooling system 300 includes a vapor compression system 330 (e.g., mechanical cooling system, air-cooled vapor compression system, chiller system, air-cooled chiller system). For example, the vapor compression system 330 may be a part of an air-cooled chiller. The vapor compression system 330 includes a working fluid circuit 334 (e.g., vapor compression circuit, first working fluid circuit) configured to circulate a working fluid, such as a refrigerant, therethrough with a compressor 336 (e.g., screw compressor, centrifugal compressor, compressor system) disposed along the working fluid circuit 334. The working fluid circuit 334 also includes a flash tank 332, a condenser 338 (e.g., first condenser, heat exchanger, air-cooled condenser), and expansion valves or devices 340. As shown in the illustrated embodiment, at least a portion 335 of the working fluid circuit 334 may extend through the electronic equipment 301, thereby enabling cooling of the electronic equipment 301 via the working fluid directed along the working fluid circuit 334. The components of the working fluid circuit 334 enable heat transfer between the working fluid and other fluids (e.g., air, water) in order to provide cooling to the electronic equipment 301.

Some examples of working fluids that may be used as refrigerants in the vapor compression system 330 are hydrofluorocarbon (HFC) based working fluids, for example, R-410A, R-407, R-134a, hydrofluoro olefin (HFO), “natural” working fluids like ammonia (NH3), R-717, carbon dioxide (CO2), R-744, or hydrocarbon-based working fluids, water vapor, or any other suitable working fluid. Other possible working fluids that may be circulated through the vapor compression system 330 include R-123, R-514A, R-1224yd, R-1233zd, R-134a, R-1234ze, R-1234yf, R-1311, and R-32. In some embodiments, the vapor compression system 330 may be configured to efficiently utilize working fluids having a normal boiling point of about 19 degrees Celsius (66 degrees Fahrenheit or less) at one atmosphere of pressure, also referred to as low pressure working fluids, versus a medium pressure working fluids, such as R-134a. As used herein, “normal boiling point” may refer to a boiling point temperature measured at one atmosphere of pressure.

The vapor compression system 330 may further include a control panel 344 (e.g., a controller) that has an analog to digital (A/D) converter 346, a microprocessor 348, a non-volatile memory 350, and/or an interface board 352. In some embodiments, the vapor compression system 330 may use one or more of a variable speed drive (VSDs) 354 and a motor 356. The motor 356 may drive the compressor 336 and may be powered by the VSD 354. The VSD 354 receives alternating current (AC) power having a particular fixed line voltage and fixed line frequency from an AC power source and provides power having a variable voltage and frequency to the motor 356. In other embodiments, the motor 356 may be powered directly from an AC or direct current (DC) power source. The motor 356 may include any type of electric motor that can be powered by the VSD 354 or directly from an AC or DC power source, such as a switched reluctance motor, an induction motor, an electronically commutated permanent magnet motor, or another suitable motor.

The compressor 336 may be configured to pressurize and/or compress a working fluid vapor received from the electronic equipment 301 and may direct the working fluid vapor along the working fluid circuit 334 toward the condenser 338. In certain embodiments, the working fluid vapor may be delivered from the compressor 336 to an oil separator 358 configured to separate oil from the working fluid vapor. In such embodiments, the working fluid vapor is then directed toward the condenser 338, and the oil is returned to the compressor 336. In other embodiments, the compressor 336 may be an oil-less compressor (e.g., magnetic bearing compressor), and the working fluid vapor is delivered from the compressor 336 to the condenser 338 (e.g., without passing through an oil separator, such as the oil separator 358). In such embodiments, the oil separator 358 is omitted.

The working fluid vapor delivered to the condenser 338 may transfer heat to a cooling fluid at the condenser 338. For example, the cooling fluid may be ambient air 360 forced across heat exchanger coils of the condenser 338 by condenser fans 362. The working fluid vapor may condense to a working fluid liquid in the condenser 338 as a result of thermal heat transfer with the cooling fluid (e.g., the ambient air 360). The liquid working fluid exits the condenser 338 and then flows through a first expansion device 364 (e.g., the expansion device 340, an electronic expansion valve). The first expansion device 364 may be a flash tank feed valve configured to control flow of the liquid working fluid to the flash tank 332. The first expansion device 364 is also configured to lower the pressure of (e.g., expand) the liquid working fluid received from the condenser 338. During the expansion process, a portion of the liquid may vaporize, and thus, the flash tank 332 may be used to separate the vapor from the liquid received from the first expansion device 364. Additionally, the flash tank 332 may provide for further expansion of the liquid working fluid due to a pressure drop experienced by the liquid working fluid when entering the flash tank 332 (e.g., due to a rapid increase in volume experienced when entering the flash tank 332).

The vapor in the flash tank 332 may exit and flow to the compressor 336. For example, the vapor may be drawn to an intermediate stage or discharge stage of the compressor 336 (e.g., not the suction stage). A valve 366 (e.g., an economizer valve, solenoid valve) may be included in the working fluid circuit 334 to control flow of the working fluid vapor from the flash tank 332 to the compressor 336. In some embodiments, when the valve 366 is open (e.g., fully open), additional liquid working fluid within the flash tank 332 may vaporize and provide additional subcooling of the liquid working fluid within the flash tank 332. The liquid working fluid that collects in the flash tank 332 may be at a lower enthalpy than the liquid working fluid exiting the condenser 338 due to the expansion in the first expansion device 364 and/or the flash tank 332. The liquid working fluid may flow from the flash tank 332, through a second expansion device 368 (e.g., the expansion device 340, an orifice), and to the electronic equipment 301 (e.g., via the portion 335 of the working fluid circuit 334 that extends to and from the electronic equipment 301). In some embodiments, the working fluid circuit 334 may also include a valve 370 (e.g., a drain valve) configured to regulate flow of liquid working fluid from the flash tank 332 to the electronic equipment 301. For example, the valve 370 may be controlled (e.g., via the control panel 344) based on an amount of suction superheat of the working fluid.

The liquid working fluid delivered to the electronic equipment 301 may absorb heat from the computer components 303 disposed within and/or thermally coupled to the computer enclosure 302, such that the liquid working fluid directed to the electronic equipment 301 may undergo a phase change to become working fluid vapor. For example, the working fluid circuit 334 may be configured to circulate the working fluid along the portion 335 from the flash tank 332 to the electronic equipment 301 and from the electronic equipment 301 to the compressor 336 (e.g., without an intermediate stage of heat exchange, such as via an evaporator and/or a CDU heat exchanger), thereby enabling cooling of the electronic equipment 301 via the working fluid. Said another way, the portion 335 of the working fluid circuit 334 may extend directly to the electronic equipment 301 without any intervening heat exchange components. For example, while the portion 335 may include certain valves, sensors, filters, pumps, and/or other fluid conveyance devices, the portion 335 of working fluid circuit 334 may not include a heat exchanger, such as a CDU heat exchanger, configured to exchange heat between a conditioning fluid circulated between the CDU and an evaporator and a coolant circulated between the CDU and the electronic equipment. Additionally, the working fluid circuit 334 may not include an evaporator configured to exchange heat between a working fluid circulated along the working fluid circuit and a conditioning fluid circulated between the evaporator and the electronic equipment. Thus, by extending at least the portion 335 of the working fluid circuit 334 to the electronic equipment 301, one or more stages of heat exchange and/or heat transfer included in certain systems, such as systems having a CDU heat exchanger and/or multiple coolant loops, may be omitted, which may enable operation of the computer cooling system 300 which reduced energy consumption.

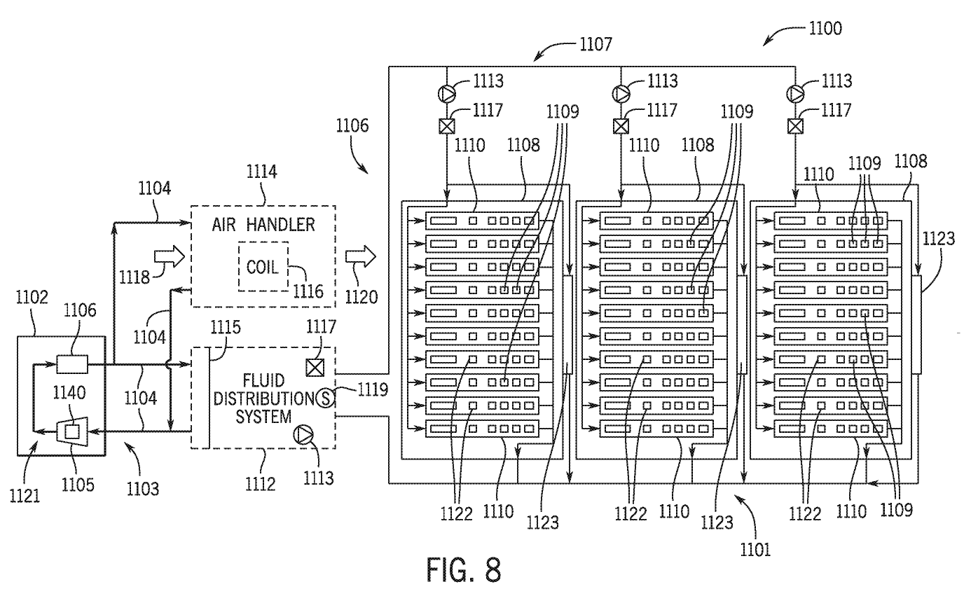

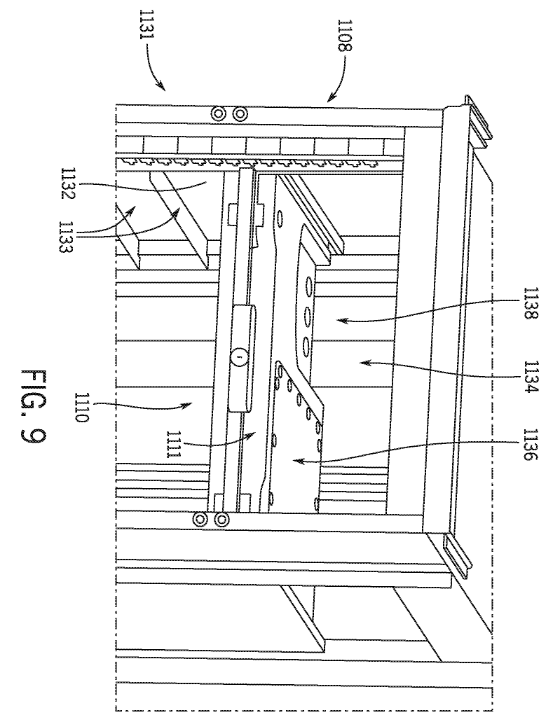

FIG. 8 is a schematic of an embodiment of a cooling system 1100 (e.g., computer cooling system, electronic equipment cooling system, data center cooling system, cooling system 300) configured to provide cooling to electronic equipment 1101. The cooling system 1100 includes a chiller system 1102 (e.g., vapor compression system 330) configured to generate (e.g., cool) a working fluid 1104 (e.g., cooling fluid, two-phase fluid) that is directed to the electronic equipment 1101 (e.g., electronic equipment 301) to cool the electronic equipment 1101. In some embodiments, the chiller system 1102 may be an air-cooled chiller. For example, the chiller system 1102 may operate in a manner similar to that described above with respect to the vapor compression system 330, and may include a working fluid circuit 1103 (e.g., working fluid circuit 334) having a compressor system 1105 (e.g., compressor 336) and one or more condensers 1106 (e.g., condenser 338, condenser coils, heat exchangers), among other components (e.g., expansion valve(s), flash tank, motor, VSD, etc.). In certain embodiments, the compressor system 1105 may circulate the working fluid 1104 along the working fluid circuit 1103 (e.g., along a portion 1107 of the working fluid circuit 1103) to the electronic equipment 1101 to place the working fluid 1104 in a heat exchange relationship with the electronic equipment 1101. The working fluid 1104 may absorb heat from the electronic equipment 1101 (e.g., cool the electronic equipment 1101) and may be delivered back to the compressor system 1105. In an embodiment of the chiller system 1102 configured as an air-cooled chiller, the condenser(s) 1106 may enable transfer of heat from the working fluid 1104 to ambient air, thereby cooling the working fluid 1104 and enabling rejection of heat absorbed by the working fluid 1104 from the electronic equipment 1101. However, it should be appreciated that the chiller system 1102 may include other configurations and/or components, such as a water-cooled chiller, a cooling tower, a dry cooler, another suitable component or system, or any combination thereof. In some embodiments, the cooling system 1100 may include an air handler 1114 (e.g., air handling unit) having a heat exchanger 1116 (e.g., coil) configured to receive the working fluid 1104 to cool an air flow 1118 directed across the heat exchanger 1116 to generate a cooled air flow 1120. The cooled air flow 1120 may be directed to the electronic equipment 1101 to cool the electronic equipment 1101.

In the illustrated embodiment, the electronic equipment 1101 includes a plurality of cabinets 1108 (e.g., racks 102, server cabinet, computer cabinet, electronics cabinet), and each cabinet 1108 is configured to support a respective plurality of computer enclosures 1110 (e.g., computer enclosure 302). Each computer enclosure 1110 is configured to contain, house, and/or support one or more computer components 1109 (e.g., computer componentry 303), such as one or more server trays (e.g., server trays 104), computer chips, integrated circuits, circuit boards, communication circuitry, processors, servers, memories, routers, switches, controllers, heat-generating components (e.g., heat-generating components 164), and/or other computer hardware. In some embodiments, one or more of the cabinets 1108 may be a computer server rack, a computer equipment rack, a server rack, a server chassis, or other suitable structure configured to support one or more of the computer enclosures 1110. The computer enclosures 1110 may include a rack server enclosure, a server tray enclosure, a blade server enclosure, a cold plate enclosure, a fluid enclosure, an immersion enclosure, a frame or other support structure, another suitable enclosure configured to contain and/or support electronic components (e.g., computer components 1109), or any combination thereof. The cabinets 1108 may be disposed within an embodiment of a building configured as a data center.

During operation, the electronic equipment 1101 may generate heat, which may cause a temperature of the computer components 1109 within and/or thermally coupled to the computer enclosures 1110 to increase. It is desirable to maintain the temperature of the computer components 1109 disposed within and/or thermally coupled to the computer enclosures 1110 below applicable temperature thresholds in order to enable proper operation of the computer components 1109 and to avoid operational interruptions. Accordingly, present embodiments include the cooling system 1100 configured to supply the working fluid 1104 to the cabinets 1108 and/or the computer enclosures 1110 to absorb heat generated by the computer components 1109 and reject the heat to another suitable location or environment.

As will be appreciated, some systems utilized to cool computer components may include an HVAC&R system having a working fluid circuit, a conditioning fluid circuit configured to circulate a conditioning fluid, and a coolant circuit configured to circulate a coolant. During operation of such systems, the working fluid circuit (e.g., refrigeration circuit 111) and the conditioning fluid circuit (e.g., primary coolant loop 120) may be in a heat exchange relationship to enable transfer of heat from the conditioning fluid to the working fluid, while the conditioning fluid circuit and the coolant circuit (e.g., secondary coolant loop 130) may be in a heat exchange relationship to enable transfer of heat from the coolant fluid to the conditioning fluid. For example, such systems may include a coolant distribution unit (CDU) (e.g., CDU 106) having a heat exchanger configured to establish a heat exchange relationship between the conditioning fluid circuit and the coolant circuit. The coolant circuit may extend from the CDU to the computer equipment to place the coolant in a heat exchange relationship with the computer equipment in order to absorb heat generated by the computer equipment.

Various embodiments of the cooling system 1100 do not include a CDU having a heat exchanger configured to place a conditioning fluid and a coolant in a heat exchange relationship. Present embodiments also may not include a separate coolant circuit in addition to the working fluid circuit 1103 of the chiller system 1102. Instead, the cooling system 1100 is configured to circulate the working fluid 1104 along the working fluid circuit 1103 between aspects of the chiller system 1102 (e.g., the compressor system 1105 and/or the condensers 1106 of the chiller system 1102) and the electronic equipment 1101 (e.g., cabinets 1108, computer enclosures 1110, fluid enclosures). Thus, the working fluid circuit 1103 may place the working fluid 1104 in a heat exchange relationship with the computer components 1109 disposed within and/or thermally coupled to the computer enclosures 1110. For example, the working fluid circuit 1103 may include one or more flow paths that extend within the cabinets 1108 and/or within one or more of the computer enclosures 1110. In certain embodiments, the working fluid 1104 may be circulated through the computer enclosure 1110, such as via a tube, conduit, flow path, channel, vessel, chilled plate, cold plate, fluid enclosure, immersion cooling techniques (e.g., direct contact with one or more computer components 1109), or any combination thereof. In this way, one or more stages of heat transfer typically included in certain systems may be omitted, which may enable operation of the chiller system 1102 with reduced energy consumption.

In some embodiments, the cooling system 1100 (e.g., the working fluid circuit 1103) may also include a fluid distribution system 1112 configured to enable distribution of the working fluid 1104 to the electronic equipment 1101 (e.g., to each cabinet 1108, to each computer enclosure 1110). The working fluid circuit 1103 and/or the fluid distribution system 1112 may include one or more components, such as one or more pumps 1113, filters 1115, valves 1117, sensors 1119, bypass conduits, and so forth that enable selective distribution of the working fluid 1104 to the electronic equipment 1101. For example, the fluid distribution system 1112 may include one or more sensors 1119 configured to detect a parameter indicative of a quality or characteristic of the working fluid 1104 (e.g., particle concentration, chemical component) directed to the cabinets 1108 and/or computer enclosures 1110. In some embodiments, the fluid distribution system 1112 may include an in-line spectrometry sensor disposed along the working fluid circuit 1103. The fluid distribution system 1112 may include certain components associated with a respective one of the cabinets 1108. For example, the fluid distribution system 1112 may include multiple pumps 1113 and/or valves 1117 configured to service (e.g., regulate flow of the working fluid 1104) to one or more of the cabinets 1108 and/or computer enclosures 1110. In certain embodiments, each cabinet 1108 and/or computer enclosure 1110 may be associated with a corresponding pump 1113 and/or valve 1117. Further, in certain embodiments, one or more of the valves 1117 may correspond to an expansion device (e.g., expansion device 368) configured to decrease the pressure of the working fluid 1104 before delivering the working fluid 1104 to the electronic equipment 1101. As will be appreciated, the cooling system 1100 may include any number of pumps 1113 and/or valves 1117 to enable selective distribution of the working fluid 1104 to the electronic equipment 1101 (e.g., to each of the cabinets 1108 and/or computer enclosures 1110). In this way, components of the fluid distribution system 1112 (e.g., pumps 1113, valves 1117) may be actuated to suspend flow of the working fluid 1104 to one of the cabinets 1108 and/or computer enclosures 1110, while enabling flow of the working fluid 1104 to remaining cabinets 1108 and/or computer enclosures 1110. In some embodiments, the fluid distribution system 1112 may be configured to regulate flow of a respective portion of the working fluid 1104 to each computer enclosure 1110 disposed within the cabinet 1108 (e.g., via corresponding valves 1117 associated with each computer enclosure 1110).

In some embodiments, the fluid distribution system 1112 may include one or more filters 1115 (e.g., permeable membrane) configured to enable flow of the working fluid 1104 therethrough and to capture one or more particles and/or contaminants within the flow of working fluid 1104. One or more of the components of the fluid distribution system 1112 may be contained in a dedicated housing or unit, distributed along the working fluid circuit 1103 at other locations, integrated within one or more of the cabinets 1108, integrated with the chiller system 1102, or any combination thereof.

In certain embodiments, the portion 1107 of the working fluid circuit 1103 that extends to the electronic equipment 1101 (e.g., extends through one or more of the cabinets 1108) may be defined by any suitable component disposed within and/or thermally coupled to the cabinet 1108 (e.g., one or more fluid enclosures disposed within the cabinets 1108). Said another way, the portion 1107 of the working fluid circuit 1103 may be at least partially defined by one or more of the cabinets 1108, one or more of the computer enclosures 1110, one or more cold plates 1122 (e.g., heat exchangers, fluid enclosures) coupled to or disposed within one or more of the computer enclosures 1110, a heat exchanger 1123 (e.g., rear door heat exchanger) disposed within the cabinet 1108, or any combination thereof. For example, a heat exchange interface between the working fluid 1104 and the computer component 1109 may take any of various forms, including direct immersion (e.g., direct thermal contact) of the computer component 1109 within the working fluid 1104, thermal contact between the computer component 1109 and the working fluid 1104 via the cold plate 1122 configured to receive the working fluid 1104, or a combination thereof.

For example, in certain embodiments, the computer component 1109 may be positioned within an interior volume (e.g., pressure vessel) defined by the computer enclosure 1110 (e.g., fluid enclosure). The interior volume of the computer enclosure 1110 may be or include a pressure vessel (e.g., fluid enclosure) configured to receive the working fluid 1104, such that the computer component 1109 disposed therein is immersed in the working fluid 1104 and cooled via immersion cooling techniques. In other embodiments, the computer enclosure 1110 may include the cold plate 1122 (e.g., cold plate, chilled plate, fluid enclosure) disposed within the interior volume and operable to receive the working fluid 1104. The cold plate 1122 may be engaged with (e.g., thermally coupled to, physically coupled to) the computer component 1109 to facilitate heat exchange between the working fluid 1104 and the computer component 1109 (e.g., via a structure of the cold plate). Additionally, or alternatively, the computer component 1109 may be positioned external to the computer enclosure 1110 and may be thermally coupled to the cold plate 1122 to enable heat exchange between the working fluid 1104 and the computer component 1109. In any case, the computer component 1109 may be placed in a heat exchange relationship with the working fluid 1104 of the chiller system 1102, thereby enabling the working fluid 1104 to absorb heat from (e.g., cool) the computer component 1109.

Additionally, or alternatively, one or more of the cabinets 1108 may include the heat exchanger 1123. The heat exchanger 1123 may be configured to transfer heat from within the cabinet 1108 (e.g., heat generated by the electronic equipment 1101 within the cabinet 1108) to the working fluid 1104 directed through the heat exchanger 1123. For example, in certain embodiments, air (e.g., ambient air) may be directed through and/or across the electronic equipment 1101 (e.g., computer enclosures 1110 and/or computer components 1109) to absorb heat from the electronic equipment 1101. In embodiments in which the heat exchanger 1123 is configured as a rear door heat exchanger, the heat exchanger 1123 may be positioned within a respective cabinet 1108 supporting the electronic equipment 1101 downstream of the electronic equipment 1101 (e.g., relative to a flow direction of the air flow across the electronic equipment 1101). The heat exchanger 1123 may circulate the working fluid 1104 therethrough, thereby enabling the air flow to transfer heat to the working fluid 1104. In any case, the portion 1107 of the working fluid circuit 1103 may enable transfer of heat from within the cabinet 1108 (e.g., transfer of heat generated by the computer components 1109 within the cabinet 1108) to the working fluid 1104 directed along the working fluid circuit 1103. After absorbing heat from the electronic equipment 1101, the working fluid 1104 may be directed along an additional portion 1121 of the working fluid circuit 1103 defined at least in part by the compressor system 1105 and the condensers 1106, thereby enabling rejection of the heat and cooling of the working fluid 1104 (e.g., via thermal heat transfer with a cooling fluid, such as ambient air, directed across the condensers 1106).

While the illustrated embodiment includes the portion 1107 of the working fluid circuit 1103 extending to the electronic equipment 1101, other embodiments of the cooling system 1100 may include a conditioning fluid circuit that extends from the chiller system 1102 to the electronic equipment 1101. Said another way, the portion 1107 of the working fluid circuit 1103 that operates to circulate the working fluid 1104 to the electronic equipment 1101 may instead be a conditioning fluid circuit configured to direct a conditioning fluid that is cooled by the chiller system to the electronic equipment, thereby placing the conditioning fluid in a heat exchange relationship with the electronic equipment 1101. For example, in such embodiments, at least a portion of the conditioning fluid circuit may extend through an evaporator of the chiller system 1102. The chiller system 1102 may therefore operate to circulate the working fluid 1104 to the evaporator of the chiller system 1102. The evaporator may enable transfer of heat from the conditioning fluid circulated along the conditioning fluid circuit and through the evaporator to the working fluid circulated through the evaporator, thereby cooling the conditioning fluid. Thereafter, the conditioning fluid may be directed to the electronic equipment 1101 via the conditioning fluid circuit to absorb heat generated by the electronic equipment 1101.

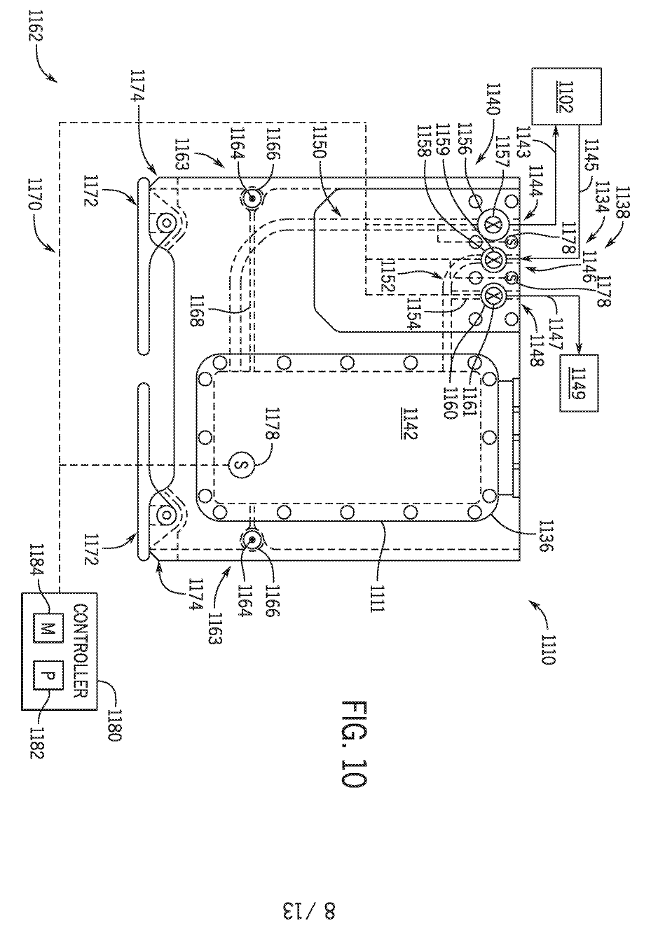

FIG. 9 is a perspective view of an embodiment of the cabinet 1108 (e.g., rack 102), which may be employed in a cooling system (e.g., computer cooling system), such as the data center cooling system 100 and/or the cooling system 1100. As noted above, the cabinet 1108 may be configured to support a respective plurality of computer enclosures 1110, and each computer enclosure 1110 may be configured to contain, house, and/or support one or more computer components 1109. To this end, the cabinet 1108 may include a mounting system 1131 having one or more supports 1132, 1133 (e.g., flanges, braces, brackets, racks) configured to support a respective computer enclosure 1110. For example, in the illustrated embodiment, the support 1132 of the mounting system 1131 is illustrated as supporting the computer enclosure 1110, and the mounting system 1131 includes empty supports 1133 configured to support additional computer enclosures 1110 (e.g., integrated circuit assemblies, server enclosures, server blades) via the mounting system 1131.

In certain embodiments, the computer enclosure 1110 may include a fluid conveyance system 1134 configured to facilitate flow of working fluid (e.g., working fluid 1104) and/or conditioning fluid through a pressure vessel 1111 (e.g., working fluid pressure vessel, conditioning fluid pressure vessel, cold plate, chilled plate, fluid enclosure) of the computer enclosure 1110 (e.g., along various flow paths of the fluid conveyance system 1134 defined by and/or supported by the computer enclosure 1110), thereby enabling direct or proximal (e.g., indirect) heat exchange with associated computer components (e.g., computer components 1109). For example, in certain embodiments, one or more of the computer components 1109 may be disposed and/or positioned within a cavity or interior volume of the pressure vessel 1111 (e.g., fluid enclosure), thereby enabling the computer components 1109 to be placed in direct heat exchange (e.g., direct thermal contact) with the working fluid and/or conditioning fluid directed through the pressure vessel 1111. In the illustrated embodiment, a panel 1136 (e.g., cover) is positioned adjacent computer components 1109 disposed within (e.g., internal to) the cavity and operates to form a boundary (e.g., sealing boundary) of the pressure vessel 1111 (e.g., fluid enclosure). In certain embodiments, the panel 1136 may be coupled (e.g., bolted, fastened) to the pressure vessel 1111 via one or more fasteners to secure the computer components 1109 within the cavity defined by the pressure vessel 1111.

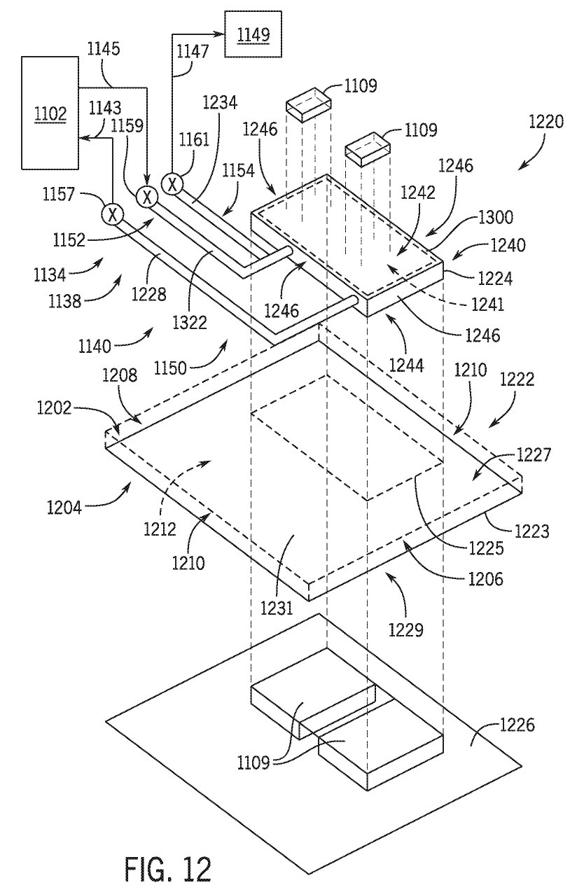

Additionally, or alternatively, in certain embodiments, one or more of the computer components 1109 may not be positioned within the pressure vessel 1111, and instead, may be mounted (e.g., mounted externally) and/or coupled to the pressure vessel 1111 and/or to the computer enclosure 1110. In such embodiments, the computer components 1109 may be in contact (e.g., physical contact, indirect thermal communication with) and/or are in close proximity to (e.g., within a threshold distance of) the pressure vessel 1111. In such embodiments, the pressure vessel 1111 may be or include a cold plate (e.g., cold plate 1122), whereby the computer components 1109 may be cooled via indirect heat exchange with the working fluid and/or conditioning fluid directed through the pressure vessel 1111 (e.g., cold plate, fluid enclosure). For example, in certain embodiments, the computer enclosure 1110 may be, include, and/or define a frame having one or more pressure vessels 1111 (e.g., fluid enclosures), and each of the pressure vessels 1111 may operate in a manner similar to that described above with respect to the cold plates 162 and/or cold plates 1122. Said another way, in certain embodiments, the pressure vessel 1111 may correspond to a cold plate, and one or more computer components (e.g., computer components 1109, heat-generating components 164) in contact with (e.g., mounted to) and/or within a threshold distance of the cold plate may be cooled via indirect heat exchange with the working fluid and/or conditioning fluid directed through the cold plate, as described in greater detail below with respect to FIG. 12.

In certain embodiments, aspects of the fluid conveyance system 1134 may at least partially define the portion 1107 of the working fluid circuit 1103 that extends to the electronic equipment 1101. For example, the fluid conveyance system 1134 may include portals 1138 in fluid communication with the cavity of the pressure vessel 1111. These portals 1138 may serve as entry points into the pressure vessel 1111 and/or exit points out of the pressure vessel 1111 along respective flow paths that fluidly couple the computer enclosure 1110 with a cooling fluid circuit (e.g., working fluid circuit 1103, conditioning fluid circuit). The flow paths (e.g., including the portals 1138) may facilitate extraction and replacement of working fluid or conditioning fluid in the pressure vessel 1111. Specifically, the flow paths may include a liquid feed path, a low-pressure suction path, and a service vacuum path, as described in greater detail below. In one embodiment, the fluid conveyance system 1134 includes three separate ports (e.g., a liquid feed port, a low-pressure suction port, and a service vacuum port) that at least partially define these paths. Flow of the working fluid and/or conditioning fluid through these paths may be controlled via valving (e.g., electric valves [EVs], electronic expansion valves [EEVs]). For example, an EV or EEV may be positioned within a respective port and/or along a respective flow path, and the EV or EEV may be controlled to manage flow through the respective port and/or along the respective flow path. It should be noted that any number of ports may be employed. For example, redundant ports may be provided (e.g., a primary liquid feed port, a backup liquid feed port, a primary low pressure suction port, a backup low pressure suction port, a primary service vacuum port, and a backup service vacuum port). Further, in one embodiment, only two ports are employed and valving of the fluid conveyance system 1134 may be used to redirect flow depending on an operational mode of the cooling system (e.g., valving may direct flow into the service vacuum path via the low-pressure suction port and no dedicated service vacuum port is provided).

FIG. 10 is a schematic plan view of an embodiment of the computer enclosure 1110 showing flow paths 1140 of the fluid conveyance system 1134 into and out of a cavity 1142 of the pressure vessel 1111 (e.g., fluid enclosure) via the portals 1138, in accordance with an embodiment of the present disclosure. For example, the flow paths 1140 (e.g., flow channels) may include a low-pressure suction flow path 1143, a liquid feed path 1145, and a service vacuum path 1147. The low-pressure suction flow path 1143 and the liquid feed path 1145 may be fluidly coupled to a cooling system, such as the chiller system 1102, thereby enabling supply of cooled cooling fluid (e.g., cooled working fluid 1104, conditioning fluid) to the pressure vessel 1111 via the liquid feed path 1145 and return of heated cooling fluid to the chiller system 1102 via the low-pressure suction flow path 1143. For example, in certain embodiments, the low-pressure suction flow path 1143 and the liquid feed path 1145 may at least partially define the portion 1107 of the working fluid circuit 1103 that extends to and/or through the electronic equipment 1101. The service vacuum path 1147 may be fluidly coupled to a vacuum manifold system 1149 configured to operate to draw a vacuum on the pressure vessel 1111, thereby enabling extraction of fluid (e.g., air, conditioning fluid, working fluid) from the pressure vessel 1111, as discussed in greater detail below.

Each of the low-pressure suction flow path 1143, the liquid feed path 1145, and the service vacuum path 1147 may be further defined by the computer enclosure 1110 and/or the pressure vessel 1111. For example, the computer enclosure 1110 may include a suction port 1144 and a suction flow channel 1150 extending from the suction port 1144 to the pressure vessel 1111 that further define the suction flow path 1143. The computer enclosure 1110 may also include a liquid feed port 1146 and a liquid feed channel 1152 extending from the liquid feed port 1146 to the pressure vessel 1111 to further define the liquid feed path 1145, and a service vacuum port 1148 and a vacuum flow channel 1154 extending from the service vacuum port 1148 to the liquid feed channel 1152. In certain embodiments, the flow paths 1140 may be further defined by and/or may include bores positioned there along and configured to receive valves (e.g., valves 1117) of the fluid conveyance system 1134, thereby enabling the valves to regulate flow (e.g., extraction and/or replacement) of the working fluid and/or conditioning fluid into and/or out of the pressure vessel 1111. For example, in the illustrated embodiment, the fluid conveyance system 1134 includes a low-pressure suction valve bore 1156 configured to receive a low-pressure suction valve 1157, a liquid feed EEV bore 1158 configured to receive a liquid feed EEV 1159, and a vacuum valve bore 1160 configured to receive a vacuum valve 1161. As described in greater detail below, the valves 1157, 1159, 1161 may be controlled (e.g., via a controller) to regulate extraction and/or replacement (e.g., circulation) of working fluid and/or conditioning fluid into the computer enclosure 1110 (e.g., along the flow paths 1140 and into the pressure vessel 1111). The computer enclosure 1110 may also include bulkhead fittings for engagement with the portals 1138. In certain embodiments, the cavity 1142 may be referred to as a “chip cavity” because it may house and/or be placed adjacent computer chips to facilitate cooling of the computer chips via working fluid and/or conditioning fluid passing through the cavity 1142.

In certain embodiments, it may be desirable to maintain engagement between the computer enclosure 1110 (e.g., fluid enclosure, pressure vessel 1111) and the cabinet 1108 until certain conditions within the computer enclosure 1110 are satisfied, thereby avoiding unintentional release of fluid from the computer enclosure 1110. To this end, the computer enclosure 1110 may include an interlock system 1162 configured to regulate a fluid connection between the pressure vessel 1111 and the flow paths 1140. For example, the interlock system 1162 may include one or more interlocks 1163 (e.g., mechanical interlocks, electrical interlocks, magnetic interlocks) distributed about the computer enclosure 1110, whereby the interlocks 1163 are configured to transition between an engaged position and a disengaged position based on a pressure and/or fluid level within the computer enclosure 1110 (e.g., within the pressure vessel 1111). In the engaged position, the interlocks 1163 (e.g., the interlock system 1162) may be configured to maintain engagement between the computer enclosure 1110 and the cabinet 1108.

In certain embodiments, the interlock 1163 includes a rod 1164 (e.g., shaft, pin) slidably positioned within a port 1166 defined by the computer enclosure 1110. In response to a status (e.g., pressure and/or fluid level) within the computer enclosure 1110 (e.g., within the pressure vessel 1111) being above a certain threshold (e.g., higher pressure than a vacuum, greater than a threshold amount of liquid), the rod 1164 may be operable to extend beyond a boundary or perimeter (e.g., extend outside) of the computer enclosure 1110 and into engagement with a receptacle defined by the cabinet 1108 (e.g., receptacle defined by the mounting system 1131). The rod 1164 of the interlock 1163 may be fluidly coupled to the pressure vessel 1111 via a flow path 1168 and may be calibrated such that pressure above the threshold pressure applied to a first end of the rod 1164 from within the pressure vessel 1111 causes the rod 1164 to translate along the port 1166, which in turn, may cause a second end of the rod 1164 to extend beyond the port 1166 and into engagement with a receptacle of the mounting system 1131. Thus, pressure beyond a threshold (e.g., above a vacuum) present in the pressure vessel 1111 may block extraction of the computer enclosure 1110 from the cabinet 1108 (e.g., via engagement of the rod 1164 with a receptacle of the cabinet 1108) and reduce potential issues with escaped, released, and/or spilled fluid related to removal of the computer enclosure 1110 while it retains any remnant of fluid. It should be appreciated that when the fluid level within the pressure vessel 1111 is above the threshold amount, the corresponding pressure value associated with the amount of fluid within the pressure vessel is also above the threshold pressure.

The interlock system 1162 is also shown to include a latching assembly 1170 having one or more latches 1172 (e.g., cam lever latches). The latching assembly 1170 (e.g., latches 1172) may also operate to secure the computer enclosure 1110 with and release the computer enclosure 1110 from the cabinet 1108. For example, each of the latches 1172 may include a cam lock assembly 1174 configured to rotate about an axis point to transition the latch 1172 from an engaged position to a disengaged position. To release the computer enclosure 1110 from the cabinet 1108, the latch 1172 may be biased toward the disengaged position, thereby enabling one or more components of the cam lock assembly 1174 to disengage from components of the cabinet 1108. To secure the computer enclosure 1110 to the cabinet 1108, the latch 1172 may be biased toward the engaged position, thereby enabling components of the cam lock assembly 1174 to engage with components of the cabinet 1108. In certain embodiments, the latches 1172 may correspond to low pressure vacuum latches configured to respond to a control signal to release the computer enclosure 1110 from the cabinet 1108 and/or to secure the computer enclosure 1110 with the cabinet 1108. In certain embodiments, the latching assembly 1170 may include a mechanical override that enables an operator to manually release the computer enclosure 1110 from the cabinet 1108 and/or to secure the computer enclosure 1110 to the cabinet 1108.

In certain embodiments, aspects of the computer enclosure 1110, such as the fluid conveyance system 1134 (e.g., valves 1157, 1159, 1161, vacuum manifold system 1149) and/or the interlock system 1162 (e.g., the interlocks 1163, the latching assembly 1170) may be actuated based on controls. For example, during installation (e.g., during an installation cycle or operation) of the computer enclosure 1110 (e.g., into a cabinet 1108), residual air may be present within the cavity 1142 of the pressure vessel 1111. The residual air may be replaced with cooling fluid (e.g., working fluid 1104, conditioning fluid) based on a control sequence initiated by a controller 1180 (e.g., control system, computer enclosure controller, computer cooling system controller), thereby enabling cooling of computer components (e.g., computer components 1109) in thermal communication with the pressure vessel 1111. For example, the controller 1180 may operate to pull a vacuum on the cavity 1142 (e.g., via one or more pumps of the vacuum manifold system 1149), which may remove residual air to facilitate proper intake of the cooling fluid. Specifically, once proper attachment of the ports 1144, 1146, 1148 is confirmed (e.g., via one or more sensors 1178), the controller 1180 may send one or more control signals to the valves 1157, 1159, 1161 to initiate a vacuum cycle. For example, to initiate a vacuum cycle, the controller 1180 may send a close command to the low-pressure suction valve 1157 and to the liquid feed valve 1159, and an open command to the vacuum valve 1161, such that the only open pathway for the cavity 1142 of the pressure vessel 1111 is along the service vacuum flow path 1147 (e.g., along the service vacuum flow channel 1154 and out of the service vacuum port 1148). Upon confirming that each of the valves 1157, 1159, 1161 is in the correct position, the controller 1180 may initiate operation of the vacuum manifold system 1149 (e.g., initiate operation of one or more pumps of the vacuum manifold system 1149), thereby enabling residual air to be drawn from the pressure vessel 1111 and along the service vacuum flow path 1147 to a collection tank for subsequent processing.

Upon drawing the pressure vessel 1111 (e.g., an interior volume of the pressure vessel 1111) down to a desired pressure (e.g., down to a vacuum via the vacuum manifold system 1149), the controller 1180 may instruct the service vacuum valve 1161 to close, thereby enabling a cooling flow activation cycle (e.g., cooling cycle or operation) to begin. For example, after the service vacuum flow path 1147 is closed (e.g., via the service vacuum valve 1161), the controller 1180 may be configured to perform a hold check via the one or more sensors 1178. For example, one or more of the sensors 1178 may be configured to provide pressure data and/or flow data within the pressure vessel 1111 and/or along the flow paths 1143, 1145, 1147, which may be indicative of whether a sufficient vacuum is held (e.g., to confirm there are no substantial leaks). After confirming that a vacuum or suction is sufficiently being held, the controller 1180 may initiate an activation cycle, whereby the controller 1180 operates to maintain closure of the service vacuum valve 1161 while opening flow along the liquid feed path 1145 and the suction flow path 1143. Specifically, for example, the controller 1180 may be configured to transition the liquid feed valve 1159 toward an open position, thereby enabling fluid flow along the liquid feed flow path 1145 and through the port 1146, and transition the suction flow valve 1157 toward an open position, thereby enabling fluid flow along the suction flow path 1143 and through the port 1144. In certain embodiments, the liquid feed valve 1159 may function as an expansion valve.

Servicing and/or replacing (e.g., a service or maintenance cycle of) the pressure vessel 1111 (e.g., fluid enclosure) may involve expulsion of the working fluid and/or conditioning fluid from the cavity 1142. It is desirable to eliminate residual working fluid from within the cavity 1142 to avoid spillage or contamination of the working fluid while working on (e.g., removing) the computer enclosure 1110. To this end, the controller 1180 may also be configured to initiate a servicing control cycle to draw the working fluid and/or conditioning fluid, which may be referred to as a charge, out of the computer enclosure 1110. Specifically, to perform the servicing control cycle, the controller 1180 may be configured to block the liquid feed path 1145 (e.g., by closing the liquid feed valve 1159), block the suction flow path 1143 (e.g., by closing the suction flow valve 1157), and open the service vacuum path 1147 (e.g., by opening the service vacuum valve 1161). Thereafter, the controller 1180 may operate the vacuum manifold system 1149 to draw residual working fluid and/or conditioning fluid from within the cavity 1142, thereby enabling the computer enclosure 1110 to be removed from the cabinet 1108 (e.g., after controlling the interlock system 1162 to enable removal of the computer enclosure from the cabinet 1108).

In certain embodiments, the controller 1180 may include processing circuitry 1182 (e.g., one or more microprocessors) and a memory 1184. For example, the controller 1180 may include non-transitory code or instructions stored on a machine-readable medium (e.g., memory 1184) and that may be executed by the processing circuitry 1182 to implement the techniques disclosed herein. The memory 1184 may include volatile memory, such as read-only memory (ROM), optical drives, hard disc drives, solid-state drives, or any other non-transitory, computer-readable medium storing instructions that, when executed by the processing circuitry 1182, control operation of the fluid conveyance system 1134, as described above.

It should be appreciated that while the computer enclosure 1110 is described above as circulating fluid (e.g., working fluid 1104, conditioning fluid, cooling fluid) through the cavity 1142 of the pressure vessel 1111 (e.g., fluid enclosure) via the various flow paths 1140 to cool electronic equipment 1101 (e.g., computer components 1109) disposed within the pressure vessel 1111 (e.g., via immersion cooling techniques), in other embodiments, the computer enclosure 1110 (e.g., the pressure vessel 1111, the flow paths 1140, fluid enclosure) may be arranged or configured in a different manner to facilitate heat exchange between the fluid (e.g., working fluid 1104, conditioning fluid) and the electronic equipment (e.g., computer components 1109) disposed within and/or coupled to the computer enclosure 1110. For example, in certain embodiments, multiple pressure vessels 1111, each having corresponding computer components 1109 disposed therein, may be included within the computer enclosure 1110, and the flow paths 1140 may be configured to circulate fluid (e.g., working fluid 1104, conditioning fluid) through each of the various pressure vessels 1111. Additionally, or alternatively, the computer enclosure 1110 may be arranged and/or configured in a manner, such that a substantial portion (e.g., majority portion) of the computer enclosure 1110 corresponds to the pressure vessel 1111. That is, in certain embodiments, the computer enclosure 1110 may be arranged and/or configured in a manner such that fluid (e.g., conditioning fluid, working fluid) is introduced (e.g., directly introduced) into an interior volume of the computer enclosure 1110 (e.g., pressure vessel 1111, fluid enclosure) to provide immersion cooling for electronic equipment disposed therein. In such embodiments, the computer enclosure 1110 may still include aspects of the fluid conveyance system 1134, such as one or more of the portals 1138 (e.g., the ports 1145, 1147, 1149), flow channels 1150, 1152, 1154, bores 1156, 1158, 1160, and/or valves 1157, 1159, 1161, to enable working fluid and/or conditioning fluid to be extracted from and/or directed into the computer enclosure 1110 in a controlled manner.

Further still, in certain embodiments, the computer enclosure 1110 may include and/or may be configured to support one or more cold plates (e.g., fluid enclosures), whereby the cold plates are thermally coupled to heat-generating components (e.g., computer components 1109, heat-generating components 164) disposed within and/or coupled to the computer enclosure 1110. Said another way, in certain embodiments, the pressure vessel 1111 may correspond to, may be configured as, and/or may operate as a cold plate (e.g., cold plate 1122), and one or more computer components (e.g., computer components 1109, heat-generating components 164) may be coupled to and/or positioned within the computer enclosure 1110 such that the heat-generating components are in contact with and/or are in close proximity to the cold plate(s) (e.g., external to the cold plate). The cold plate(s) may be configured to receive a flow of fluid (e.g., working fluid 1104, conditioning fluid, IT fluid) via associated conduits, piping, and/or valving of the working fluid circuit 1103 and/or the fluid conveyance system 1134, and transfer heat from the heat-generating components to the fluid (e.g., working fluid, refrigerant), as described in greater detail below.

As discussed above, computer enclosures configured to house and/or support various electronic components (e.g., computer components 1109) may include and/or define one or more pressure vessels. The computer components may be disposed within the pressure vessels (e.g., fluid enclosures, within a chip cavity of the pressure vessels, such as the chip cavity 1142 of the pressure vessel 1111), and the pressure vessels may be configured to receive fluid (e.g., working fluid 1104, conditioning fluid, cooling fluid) to provide immersion cooling for the computer components disposed therein. Additionally, or alternatively, one or more cold plates may be mounted to and/or supported by a respective computer enclosure, and the one or more cold plates may be thermally coupled to and/or physically coupled to the computer components. Said another way, the computer components may be coupled to the cold plates such that the computer components are not disposed within an interior volume defined by the cold plate but are instead external to the interior volume. The cold plates may be configured to receive fluid (e.g., working fluid 1104, conditioning fluid, cooling fluid) to provide indirect cooling to the computer components thermally coupled thereto. Thus, the computer enclosure, the pressure vessel, and/or the cold plate(s), each of which may be generally be referred to as a fluid enclosure, may be subjected to increased pressures (e.g., increased mechanical stress) based on the introduction of fluid (e.g., working fluid 1104, conditioning fluid, pressurized working fluid) into the computer enclosure, pressure vessel, and/or cold plate. To this end, embodiments of the computer enclosures, pressure vessels, and/or cold plates discussed herein may include one or more reinforced regions configured to distribute a pressure load (e.g., distribute stress) within the computer enclosure, pressure vessel, and/or cold plate across a side or surface of the computer enclosure, pressure vessel, and/or cold plate while limiting an amount of material employed by the computer enclosure, pressure vessel, and/or cold plate (e.g., limiting a mass associated with manufacture and/or construction of the computer enclosure 1110, pressure vessel 1111, and/or the one or cold plates supported by the computer enclosure 1110).

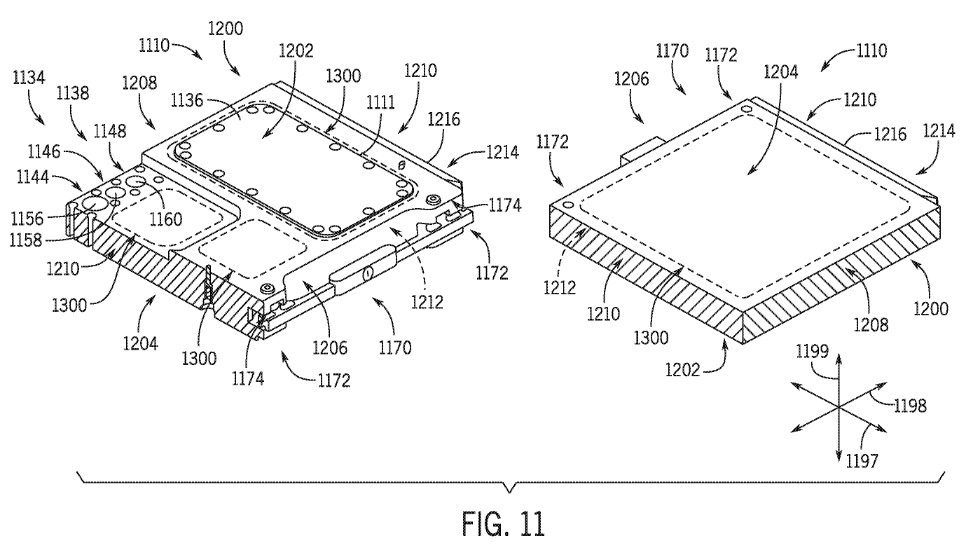

For example, FIG. 11 is a perspective view of an embodiment of a computer enclosure 1110 having one or more reinforced regions 1300 configured to distribute a pressure load associated with the computer enclosure 1110 (e.g., pressure load associated a pressure vessel defined by the computer enclosure 1110, such as the pressure vessel 1111) across one or more sides of the computer enclosure 1110, such as during periods in which a fluid (e.g., working fluid 1104) is directed under pressure into an interior volume defined by the computer enclosure 1110 (e.g., interior volume defined by the pressure vessel 1111). In this way, the reinforced regions 1300 may provide structural rigidity to the computer enclosure 1110 while limiting an amount of material utilized to form the computer enclosure 1110. To facilitate discussion, the computer enclosure 1110 is arranged along a longitudinal axis 1197, a lateral axis 1198, and a vertical axis 1199.

As shown, the computer enclosure 1110 includes a housing 1200 having a first side 1202 (e.g., top side, cover side), a second side 1204 (e.g., bottom side), a third side 1206 (e.g., front side), a fourth side 1208 (e.g., back side), and a pair of lateral sides 1210. Each of the sides 1202, 1204, 1206, 1208, 1210 may collectively define an interior volume 1212 of the computer enclosure 1110 in which electronic equipment 1101 (e.g., computer components 1109) may be disposed. In certain embodiments, the interior volume 1212 may be further separated into two or more internal volumes via partitions and/or walls extending through the interior volume 1212. For example, in certain embodiments, the interior volume 1212 may include or correspond to the pressure vessel 1111 and/or the cavity 1142 discussed above. Additionally, or alternatively, the interior volume 1212 may function as a pressure vessel (e.g., in embodiments in which a substantial or majority portion of the computer enclosure is arranged and/or configured for immersion cooling). As will be appreciated, the following description of the computer enclosure 1110 may apply to embodiments in which the computer enclosure 1110 corresponds to a pressure vessel (e.g., pressure vessel 1111, fluid enclosure) and/or embodiments in which the computer enclosure 1110 defines one or more pressure vessels (e.g., pressure vessel 1111, fluid enclosure).

As noted above, during operation of a cooling system (e.g., cooling system 1100) that provides cooling to the electronic equipment (e.g., computer components 1109) disposed within the computer enclosure 1110 (e.g., disposed within the pressure vessel 1111, which may be defined at least in part by the computer enclosure 1110), working fluid (e.g., working fluid 1104) and/or conditioning fluid may be directed into the interior volume 1212 (e.g., via the portals 1138), thereby causing a pressure load within the interior volume 1212 (e.g., pressure load within the pressure vessel 1111) to increase. As the pressure increases, forces imparted to and/or acting on the sides 1202, 1204, 1206, 1208, 1210 of the computer enclosure 1110 may induce deformation (e.g., expansion) of the computer enclosure 1110. In certain cases, increased pressure loads may cause the sides 1202, 1204, 1206, 1208, 1210 to deform beyond an upper limit deformation threshold of the computer enclosure 1110, which may be undesirable. To this end, the computer enclosure 1110 may include one or more reinforced regions 1300 configured to limit potential deformation of the computer enclosure 1110, as discussed in greater detail below.

In the illustrated embodiment, the computer enclosure 1110 also includes a mounting system 1214 having one or more rails 1216 configured to interact with and/or engage with racks (e.g., supports 1132, 1133) of a mounting system (e.g., mounting system 1131) during installation and/or removal of the computer enclosure 1110 into and/or out of a cabinet (e.g., cabinet 1108). For example, the mounting system 1214 includes a rail 1216 coupled to a lateral side 1210 of the computer enclosure 1110 and extending in a direction (e.g., horizontal direction) along the longitudinal axis 1197. The rail 1216 may be configured to enable movement of the computer enclosure 1110 relative to the mounting system 1131 of the cabinet 1108. In certain embodiments, the rail 1216 may enable movement of the computer enclosure 1110 relative to a cabinet once the latches 1172 (e.g., disposed along the third side 1206 of the computer enclosure 1110) are disengaged from respective components of the cabinet (e.g., upon transitioning the latches 1172 from an engaged position to a disengaged position).

As mentioned above, in certain embodiments, a computer enclosure may include one or more cold plates thermally coupled to computer components (e.g., computer components 1109) disposed within and/or coupled to the computer enclosure 1110, thereby enabling the cold plates to absorb heat from the computer components during operation. Said another way, a computer enclosure may be configured to support, house, and/or enclose one or more cold plates, and the cold plates may be thermally coupled to computer components (e.g., computer components) disposed external to the cold plate, thereby enabling indirect cooling for the computer components via a working fluid circulated internal to the cold plate. For example, FIG. 12 is an exploded perspective view of an embodiment of a computer cooling assembly 1220 that includes a computer enclosure 1222 (e.g., or a portion thereof, such as a frame defined by the computer enclosure 1222) configured to support, house, and/or enclose one or more cold plates 1224. In certain embodiments, the computer enclosure 1222 may include similar features to the computer enclosure 1110, such as the housing 1200 having the sides 1202, 1204, 1206, 1208, 1210 that define the interior volume 1212 and the fluid conveyance system 1134 and/or aspects thereof. Additionally, or alternatively, the computer enclosure 1222 may be a frame or other structural component(s) configured to support one or more cold plates 1224 coupled thereto. Further, while features of the interlock system 1162 are not shown in FIG. 12, it should be understood that the computer enclosure 1222 may include the interlock system 1162 and/or features thereof (e.g., interlocks 1163, latching assembly 1170).

The computer cooling assembly 1220 may also include a server tray 1226 having one or more computer components 1109 (e.g., heat-generating components) disposed thereon. In some embodiments, the computer enclosure 1222 may be configured to facilitate extraction and/or replacement of the working fluid (e.g., working fluid 1104) and/or conditioning fluid to and/or from the one or more cold plates 1224 associated with (e.g., positioned within, coupled to, integrally coupled to, supported by) the computer enclosure 1222. In an assembled configuration of the computer cooling assembly 1220, the cold plates 1224 may be positioned within and/or supported by the computer enclosure 1222 (e.g., positioned within the interior volume 1212, supported by a side of the computer enclosure 1222 that defines a frame, such as the side 1204), and the server tray 1226 may be mounted to (e.g., coupled to, bolted to) the computer enclosure 1222 (e.g., a frame, a portion of the computer enclosure 1222), such that the computer components 1109 are in physical contact with (e.g., thermal contact with) and/or in close proximity to (e.g., within a threshold distance of) the cold plates 1224. Said another way, the computer enclosure 1222 may be configured and/or designed such that the cold plate(s) 1224 align with and/or engage with the computer components 1109 in an assembled configuration of the computer cooling assembly 1220.

For example, the computer enclosure 1222 may include or define a frame 1223 (e.g., base, support). In certain embodiments, the frame 1223 may correspond to the second side 1204 of the computer enclosure 1222. The cold plates 1224 may be mounted to (e.g., coupled to) a portion 1225 (e.g., heat exchange portion) of the frame 1223 along a first surface 1227 (e.g., interior surface, cold plate mounting surface) of the frame 1223. The server tray 1226 may be mounted to the frame 1223, such that the computer components 1109 align with and abut, contact, and/or engage with the portion 1225 of the frame 1223 along a second surface 1229 (e.g., exterior surface) of the frame 1223. In certain embodiments, a thickness (e.g., material thickness) of the portion 1225 of the frame 1223 may be less than a thickness of a remaining portion 1231 of the frame 1223. Said another way, the frame 1223 may be thinner along the portion 1225 to facilitate heat exchange between the cold plate 1224 and the computer components 1109.

For example, during operation of the computer components 1109, working fluid (e.g., working fluid 1104) and/or conditioning fluid may be directed toward the cold plates 1224 via the fluid conveyance system 1134, thereby enabling the working and/or conditioning fluid directed through the cold plates 1224 to absorb heat from the computer components 1109, as described above. In certain embodiments, positioning the server tray 1226 and/or the computer components 1109 external to the computer enclosure 1222 may reduce manufacturing and/or assembly complexity, thereby reducing costs associated with the manufacture and assembly of the computer cooling assembly 1220. For example, the computer components 1109 may be coupled to the server tray 1226, and the computer enclosure 1222 (e.g., having the fluid conveyance system 1134 and/or aspects thereof) may be prepared (e.g., machined, manufactured) such that the cold plates 1224 are positioned at locations (e.g., portion 1225) corresponding to (e.g., aligning with) the computer components 1109 on the server tray 1226. In certain embodiments, aspects of the fluid conveyance system 1134, such as the portals 1138 and/or flow paths 1140 (e.g., flow channels 1150, 1152, 1154), may be provided within and/or along a surface of the computer enclosure 1222, thereby enabling working fluid and/or conditioning fluid to be directed into and/or extracted from the cold plates 1224.

For example, the suction-flow channel 1150 may be defined by a conduit 1228 (e.g., tube, suction flow conduit) configured to extend along the first surface 1227 (e.g., interior surface) of the frame 1223. In certain embodiments, the suction valve 1157 may be positioned along the conduit 1228 and/or along the low-pressure suction flow path 1143 upstream of the computer enclosure 1222 (e.g., relative to a flow direction of working and/or conditioning fluid into the computer enclosure 1222). The liquid flow channel 1152 may be defined by a conduit 1232 (e.g., liquid feed conduit) configured to extend along the surface 1227 of the frame 1223. In certain embodiments, the liquid-feed valve 1159 may be positioned along the conduit 1232 and/or along the liquid feed path 1145 upstream of the computer enclosure 1222. The vacuum flow channel 1154 may be defined by a conduit 1234 (e.g., service vacuum conduit) configured to extend along the surface 1227 of the frame 1223. In certain embodiments, the vacuum valve 1161 may be positioned along the conduit 1234 and/or along the service vacuum path 1147 upstream of the computer enclosure 1222. It should be appreciated that while the flow channels 1150, 1152, 1154 are described above as being defined by conduits 1228, 1232, 1234 extending along the surface 1227 of the frame 1223, in other embodiments, the computer enclosure 1222 may define the interior volume 1212 in which the cold plates 1224 are disposed, and the flow channels 1150, 1152, 1154 may extend through the interior volume 1212 of the computer enclosure 1222 to the cold plates 1224 in a manner similar to that described above with respect to FIG. 10.

As shown in the illustrated embodiment, the cold plate 1224 (e.g., fluid enclosure) may include a housing 1240 having a first side 1242 (e.g., top side, cover side), a second side 1244 (e.g., bottom side), and a number of lateral sides 1246. In certain embodiments, the computer components 1109 may be configured to engage with, abut, and/or contact the first side 1242 and/or the second side 1244 of the cold plate 1224 to facilitate heat exchange between the computer component 1109 and the fluid (e.g., working fluid 1104, conditioning fluid) circulated through the cold plate 1224. For example, as shown in the illustrated embodiment, the cold plate 1224 may be mounted to the surface 1227 of the frame 1223 (e.g., along the portion 1225), and the server tray 1226 may be mounted to the computer enclosure 1222, such that the one or more of the computer components 1109 contact the surface 1229 of the frame 1223 along the portion 1225 and are placed in a heat exchange relationship with the cold plates 1224, as described above. In certain embodiments, the portion 1225 of the frame 1223 may be removed, such that the computer components 1109 engage with (e.g., thermally couple to) the second surface 1244 of the cold plate 1224. For example, the portion 1225 of the frame 1223 may correspond to a cavity or recess (e.g., cutout) configured to receive the cold plate 1224, thereby enabling direct contact between the surface 1244 of the cold plate 1224 and the computer components 1109. Additionally, or alternatively, one or more computer components 1109 may be coupled to (e.g., thermally coupled to) the first side 1242 of the cold plate 1224. Thus, the computer components 1109 may be disposed external to the computer enclosure 1222, within the computer enclosure 1222, or both. In any case, the computer components 1109 may be thermally coupled to the cold plate 1224 to facilitate heat exchange therebetween.

Each of the sides 1242, 1244, 1246 of the housing 1240 may collectively define an interior volume 1241 of the cold plate 1224 (e.g., fluid enclosure). The working fluid (e.g., working fluid 1104) and/or conditioning fluid directed to the one or more cold plates 1224 may be directed into the interior volume 1241 of the one or more cold plates 1224, thereby causing a pressure load within the interior volume 1241 to increase. As the pressure increases, forces imparted to and/or acting on the sides 1242, 1244, 1246 of the cold plate 1224 may induce deformation (e.g., expansion) of the cold plate 1224. In certain cases, increased pressure loads may cause the sides 1242, 1244, 1246 to deform beyond an upper limit deformation threshold of the cold plate 1224, which may be undesirable. To this end, the cold plate 1224 may include one or more reinforced regions 1300 configured to limit potential deformation of the cold plate 1224, as discussed in greater detail below.

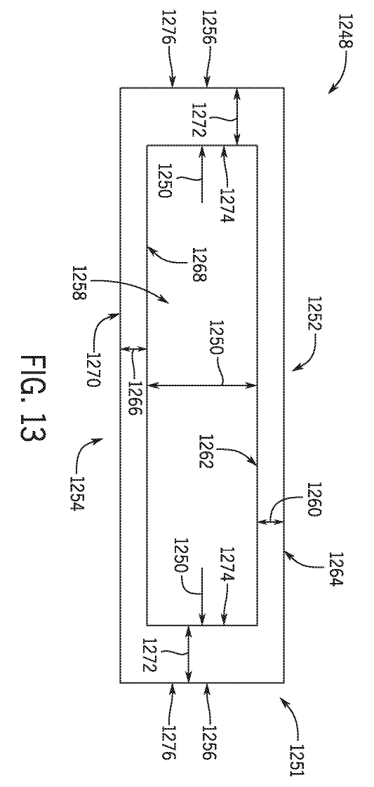

FIG. 13 is a cross-sectional view of an embodiment of a fluid enclosure 1248 (e.g., computer component fluid enclosure) for a computer cooling system or data center cooling system, such as the cooling system 1100, illustrating various forces 1250 acting on interior surfaces (e.g., inner surfaces) of the fluid enclosure 1248. As discussed herein, a fluid enclosure may refer to a computer enclosure, such as the computer enclosure 1110 described above with respect to FIG. 11, a pressure vessel, such as the pressure vessel 1111 defined by a computer enclosure, and/or a cold plate, such as the cold plate 1224 described above with respect to FIG. 12. As shown in the illustrated embodiment, the computer enclosure heat exchanger 1248 includes a housing 1251 (e.g., housing 1200 of the computer enclosure 1110, housing 1241 of the cold plate 1224) having a first side 1252 (e.g., first side 1202 of the computer enclosure 1110, first side 1242 of the cold plate 1224), a second side 1254 (e.g., second side 1204 of the computer enclosure 1110, second side 1244 of the cold plate 1224), and a number of lateral sides 1256 (e.g., third, fourth, and lateral sides 1206, 1208, 1210 of the computer enclosure 1110, lateral sides 1246 of the cold plate 1224) that collectively define an interior volume 1258 (e.g., interior volume 1212 of the computer enclosure 1110, interior volume 1258 of the cold plate 1224) of the housing 1251. The forces 1250, which are generated in response to the introduction of fluid (e.g., working fluid 1104, conditioning fluid) into the interior volume 1258 of the housing 1251, may impinge against the interior surfaces of sides 1252, 1254, 1256 of the housing 1251 and may bias the interior surfaces in an outward direction (e.g., radially outward direction relative to a central point of the fluid enclosure 1248).

For example, the first side 1252 may have a width 1260 (e.g., depth) that extends from an interior surface 1262 of the first side 1252 to an exterior surface 1264 of the first side 1252. Similarly, the second side 1254 may have a width 1266 (e.g., depth) that extends from an interior surface 1268 of the second side 1254 to an exterior surface 1270 of the second side 1254. In certain embodiments, the widths 1260, 1266 of the first and second sides 1252, 1254 of the fluid enclosure 1248 may be the same or substantially the same. Furthermore, each of the lateral sides 1256 may have a width 1272 that extends from a respective interior surface 1274 of lateral sides 1256 to a respective exterior surface 1276 of the lateral sides 1256. In certain embodiments, the width 1272 of the lateral sides 1256 may be greater (e.g., double) the width 1260 of the first side 1252 and/or that the width 1266 of the second side 1254.

As the pressure within the interior volume 1258 of the fluid enclosure 1248 (e.g., housing 1251) increases, a magnitude of the forces 1250 may increase, thereby causing the interior surfaces 1262, 1268, 1274 to expand or deform (e.g., in a radially outward direction). As the interior surfaces 1262, 1268, 1274 expand in response to the forces 1250 acting thereupon, the corresponding exterior surfaces 1264, 1270, 1276 of the housing 1251 may also expand or deform. In certain embodiments, expansion or deformation of the interior surfaces 1262, 1268, 1274 and/or exterior surfaces 1264, 1270, 1276 may exceed a deformation threshold of the housing 1251, such that widths 1260, 1266, and/or 1272 decrease. That is, the forces 1250 imparted to the housing 1251 may cause the housing 1251 to bow or expand, thereby decreasing the structural rigidity of the housing 1251 and/or reducing the structural integrity of the housing 1251.

Referring back to FIGS. 11 and 12, the housing 1200 of the computer enclosure 1110 and/or the housing 1240 of the cold plate 1224 may include the one or more reinforced regions 1300 to limit potential deformation of the computer enclosure 1110 and/or cold plate 1224 (e.g., deformation of the fluid enclosure 1248). Each of the one or more reinforced regions 1300 may extend along a respective side 1202, 1204, 1206, 1208, 1210 of the computer enclosure 1110 and/or a respective side 1242, 1244, 1246 of the cold plate 1224. In certain embodiments, the reinforced regions 1300 may be positioned at a location corresponding to a section of the computer enclosure 1110 (e.g., section of the interior volume 1212, cavity 1142, pressure vessel 1111) or cold plate 1224 that is subjected to increased pressures. For example, the computer enclosure 1110 and/or cold plate 1224 may be formed of any suitable material (e.g., cast material, alloy, aluminum, corrosion-resistant material). The material may be cast (e.g., directed under pressure into a mold), thereby forming a desired shape that serves as the computer enclosure 1110 or cold plate 1224. In certain embodiments, the desired shape may include the reinforced regions 1300 extending along one or more of the sides 1202, 1204, 1206, 1208, 1210 of the computer enclosure 1110 or along one or more of the sides 1242, 1244, 1246 of the cold plate 1224.

For example, as shown in FIG. 11, in certain embodiments, the panel 1136, which may be positioned on the first side 1202 of the computer enclosure 1110 to enclose the pressure vessel 1111, may correspond to a reinforced region 1300. Said another way, a top portion of the pressure vessel, such as the panel 1136, may include or define a reinforced region 1300. Additionally, or alternatively, the second side 1204 may include one or more reinforced regions 1300. Similarly, the second side 1244 of the cold plate 1224 may include one or more reinforced regions. Further still, additional reinforced regions 1300 may be included on the first side 1202 and/or the third, fourth, and lateral sides 1206, 1208, 1210 of the computer enclosure 1110 and/or on the lateral sides 1246 of the cold plate 1224. It should be appreciated that while FIG. 11 illustrates three reinforced regions 1300 extending along the first side 1202 of the computer enclosure 1110, the first side 1202 may include any number (e.g., one, two, four, five, or more) of reinforced regions 1300 at desired locations along the first side 1202. In certain embodiments, the desired location may correspond to an unsupported portion of the housing 1200 (e.g., portion of the housing 1200 that is greater than a threshold distance away from a support component, such as a fastener or bolt, of the computer enclosure 1110). Similarly, while a single reinforced region 1300 is illustrated as extending along the second side 1204, the second side 1204 may include any number (e.g., two, three, four, or more) of reinforced regions 1300 extending along the second side 1204. Further still, in certain embodiments, one or more of the sides 1202, 1204, 1206, 1208, 1210 or portions thereof may not include reinforced regions 1300. For example, in certain embodiments, portions of the first and/or second sides 1202, 1204 may extend across sections of the interior volume 1212 that are not subjected to fluctuating pressures, and thus, reinforced regions 1300 may not be employed in such areas along the first and/or second sides 1202, 1204. In certain embodiments, a dimension (e.g., width, thickness) of the first and/or second sides 1202, 1204 along such portions (e.g., portions that extend over sections of the interior volume 1212 that are not subjected to fluctuating pressures) may be less than a dimension (e.g., width, thickness) of the reinforced regions 1300, thereby further reducing the mass of the computer enclosure 1110, as described in greater detail below.

Furthermore, it should be appreciated that, while FIG. 12 illustrates a single reinforced region 1300 extending along the first side 1242 of the cold plate 1224 (e.g., fluid enclosure), the first side 1242 may include any number (e.g., two, three, four, or more) of reinforced regions 1300 at desired locations along the first side 1242. Further, it should be understood that the second side 1244 of the cold plate 1224 may also include any number of reinforced regions 1300.

As discussed in greater detail below, each of the reinforced regions 1300 may correspond to a geometric structure (e.g., truss structure, monocomb structure) configured to distribute a pressure load (e.g., stress) across a side of a fluid enclosure, such as the fluid enclosure 1248 (e.g., across a side 1202, 1204, 1206, 1208, 1210 of the computer enclosure 1110 and/or a side 1242, 1244, 1246 of the cold plate 1224). The reinforced regions 1300 may include one or more ribs or extensions extending from a recessed surface of the reinforced region 1300. In certain embodiments, the recessed surface may correspond to an exterior surface (e.g., exterior surface 1264, 1270, 1276) of a respective side of the fluid enclosure 1248 (e.g., computer enclosure 1110 or cold plate 1224). The ribs or extensions may be configured to engage with outer ribs or extensions of the reinforced regions 1300 (e.g., during expansion of the fluid enclosure 1248 based on the increased pressure associated with the introduction of fluid into the fluid enclosure 1248), thereby placing the reinforced regions 1300, and thus the housing 1251 (e.g., housing 1200 of the computer enclosure 1110, housing 1240 of the cold plate 1224) under tension. As the ribs or extensions engage with the outer ribs or extensions, an amount of deformation of the fluid enclosure 1248 may be limited, thereby maintaining the structural integrity and/or improving the structural rigidity of the fluid enclosure 1248. Moreover, by employing the reinforced regions 1300, decreased amounts of material may be utilized to form the fluid enclosure 1248 (e.g., computer enclosure 1110 or cold plate 1224) due to a reduced amount of material in the recessed portions of the reinforced regions 1300, thereby improving the serviceability of the fluid enclosure 1248 and/or the serviceability of a computer cooling assembly, such as the computer cooling assembly 1220, associated with the fluid enclosure 1248, as discussed in greater detail below. Said another way, the reinforced regions 1300 may enable a reduction in the mass of the fluid enclosure 1248 (e.g., reduction in the mass of a computer enclosure or computer cooling assembly configured to support the fluid enclosure 1248) while still enabling retention of pressure within the interior volume 1258 of the fluid enclosure 1248 and resistance to deformation during operation. In this way, an operator may more readily manipulate (e.g., lift, carry) and/or service the fluid enclosure 1248 (e.g., computer enclosure 1110, cold plate 1224) and/or a computer enclosure configured to house and/or support the fluid enclosure 1248 (e.g., computer enclosure 1222 of computer cooling assembly 1220). In certain embodiments, the reinforced regions 1300 may enable an operator to independently manipulate and/or service the fluid enclosure 1248 (e.g., computer enclosure 1110, cold plate 1224) and/or a computer enclosure configured to house and/or support the fluid enclosure 1248 (e.g., computer enclosure 1222 of computer cooling assembly 1220).

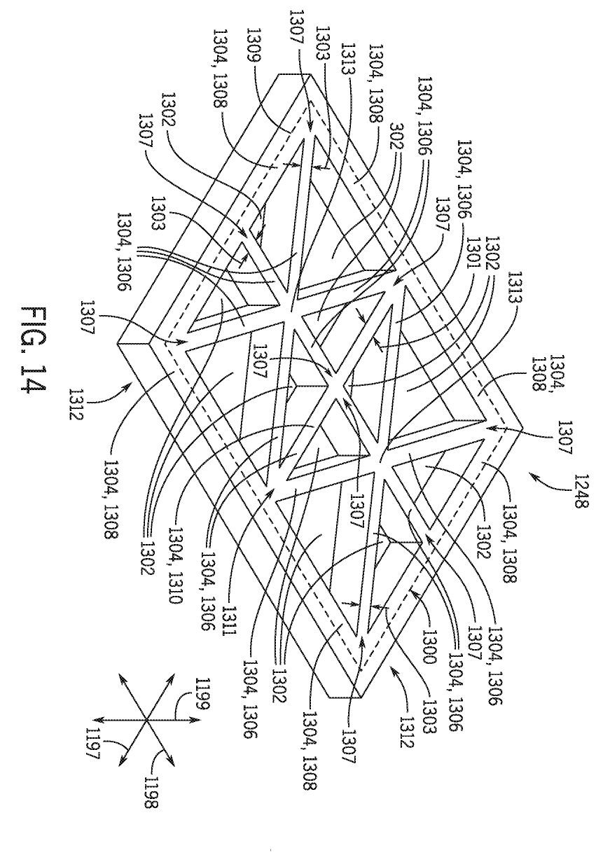

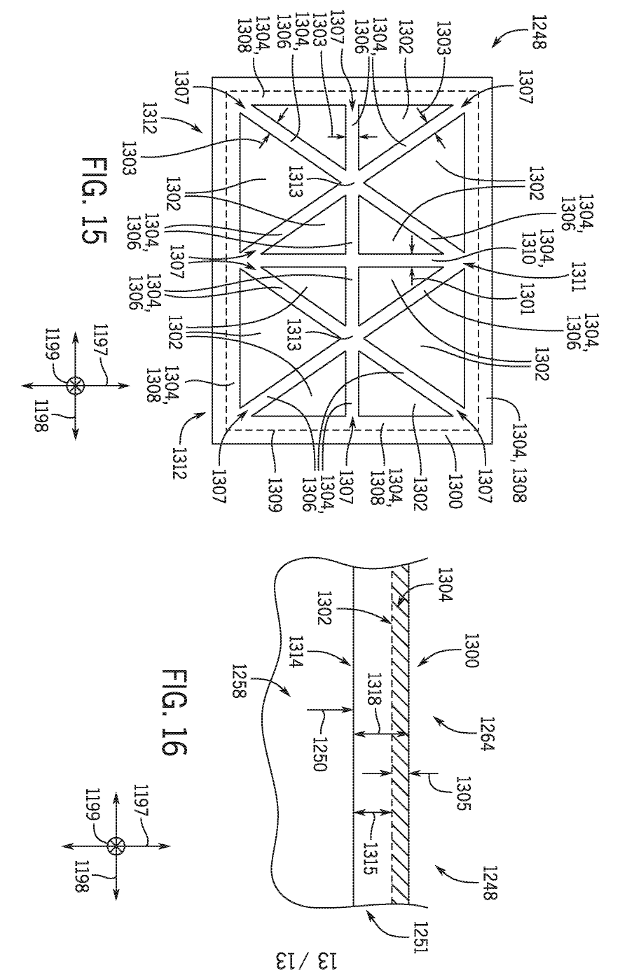

Turning now to FIGS. 14-16, various views of an embodiment of a reinforced region 1300, which may be employed by a fluid enclosure, such as the fluid enclosure 1248 (e.g., computer enclosure 1110, cold plate 1224) to limit deformation of the fluid enclosure 1248, are shown. For example, FIG. 14 is a perspective view of an embodiment of the reinforced region 1300, FIG. 15 is an overhead view of an embodiment of the reinforced region 1300, and FIG. 16 is a side view of an embodiment of the reinforced region 1300. To facilitate discussion, FIGS. 14-16 are described concurrently below. In the illustrated embodiments, the reinforced regions 1300 includes a recessed surface 1302 and one or more ribs 1304 (e.g., reinforcement ribs) extending from the recessed surface 1302 in a direction (e.g., vertical direction) along the vertical axis 1199 for a distance 1305 (e.g., height). In certain embodiments, one or more of the ribs 1304 may correspond to interior ribs 1306, while other of the ribs 1304 may correspond to outer ribs 1308 (e.g., perimeter ribs, peripheral ribs). For example, the outer ribs 1308 may define a perimeter or boundary 1309 of the reinforced region 1300, and the interior ribs 1306 may extend along the recessed surface 1302 in various directions (e.g., horizontal directions) to and from the outer ribs 1308 (e.g., to the boundary 1309 defined by the outer ribs 1308), such that ends 1307 of each of the interior ribs 1306 abut or engage the outer ribs 1308. Furthermore, in certain embodiments, the reinforced region 1300 may include one or more intermediate ribs 1310 extending between sub-sections 1312 of the reinforced region 1300. In certain embodiments, a width 1301 of the intermediate rib 1310 may be greater than a width of a respective interior rib 1306.

As shown in FIGS. 14 and 15, the reinforced region 1300 includes two sub-sections 1312 separated by an intermediate rib 1310. Each sub-section 1312 includes a number of interior ribs 1306 extending along the recessed surface 1302 in various directions (e.g., horizontal directions). For example, each sub-section 1312 may include a central point 1313, and distal ends 1307 (e.g., relative to the central point 1313) of each of the interior ribs 1306 are in abutment with and/or engaged with an outer rib 1308 and/or an intermediate rib 1310. Similarly, distal ends 1311 of the intermediate rib 1310 (e.g., relative to a central point along the intermediate rib 1310) may be configured to abut or engage one or more of the outer ribs 1308. As shown in the illustrated embodiment, each sub-section 1312 may be defined by three outer ribs 1308 and the intermediate rib 1310. For example, each sub-section 1312 is bounded by a pair of outer ribs 1308 extending in a direction (e.g., horizontal direction) along the lateral axis 1198, an additional outer rib 1308 extending between the pair of outer ribs 1308 in a direction (e.g., horizontal direction) along the longitudinal axis 1197, and the intermediate rib 1310 extending between the pair of outer ribs 1308 in a direction (e.g., horizontal direction) along the longitudinal axis 1197. Additionally, each sub-section 1312 may include one or more interior ribs 1306 extending in a direction (e.g., horizontal direction) along the lateral axis 1198 (e.g., between the additional outer rib 1308 and the intermediate rib 1310) and one or more interior ribs 1306 extending in a direction (e.g., horizontal direction) between the longitudinal axis 1197 and the lateral axis 1198 (e.g., in a diagonal direction, at a non-zero angle relative to the longitudinal axis 1197 and/or the lateral axis 1198).

It should be appreciated that while FIGS. 14 and 15 illustrate two sub-sections 1312 bounded by three outer ribs 1308 and an intermediate rib 1310, with each sub-section 1312 having six interior ribs 1306, in other embodiments, the reinforced region 1300 may include any number (e.g., one, three, four, or more) of sub-sections 1312 each having any number (e.g., two, three, four, five, seven, or more) of interior ribs 1306. Furthermore, the interior ribs 1306, the outer ribs 1308, and/or the intermediate ribs 1310 may extend in any direction (e.g., horizontal direction) along the recessed surface 1302. For example, in certain embodiments, one or more of the interior ribs 1306 may extend in a direction (e.g., horizontal direction) along the longitudinal axis 1197. Similarly, in certain embodiments, the intermediate rib 1310 may extend in a direction (e.g., horizontal direction) along the lateral axis 1198 and/or in a direction (e.g., horizontal direction) between the longitudinal axis 1197 and the lateral axis 1198 (e.g., extend in a diagonal direction). Further still, in certain embodiments, the reinforced region 1300 may not include the sub-sections 1312. In such embodiments, the intermediate rib 1310 may correspond to an interior rib 1306. As will be appreciated, the interior ribs 1306 and/or the intermediate rib 1310 may be arranged in any suitable configuration with the outer ribs 1308 that enables the housing 1251 of the fluid enclosure 1248 to withstand increased pressures while maintaining the structural integrity and limiting the mass of the fluid enclosure 1248.

For example, as noted above, fluid (e.g., working fluid 1104, conditioning fluid) may be directed into the fluid enclosure 1248 to provide cooling for electronic equipment (e.g., computer components 1109) disposed therein and/or thermally coupled thereto. As the fluid is directed into the interior volume 1258 of the fluid enclosure 1248, the pressure within the interior volume 1258 may increase. In certain cases, the increase in pressure within the interior volume 1258 may generate the forces 1250 that act against an interior surface 1314 of the reinforced region 1300 (e.g., interior surface 1262, 1268, 1274), thereby causing the interior surface 1314 of the reinforced region 1300 to expand (e.g., in a radially outward direction). As the interior surface 1314 expands, one or more of the interior ribs 1306 and/or the intermediate rib 1310 in abutment and/or engaged with the outer ribs 1308 of the reinforced region 1300 may mechanically distribute the pressure load (e.g., by bringing the reinforced region 1300 under tension). For example, the ribs 1304 may be configured to engage with one another (e.g., interior ribs 1306 and/or intermediate rib 1310 engages with the outer ribs 1308, interior ribs 1306 engage with the intermediate rib 1310), thereby limiting deformation and/or expansion of recessed surface 1302 of the reinforced region 1300 while reducing the mass associated with the fluid enclosure 1248.

For example, in certain embodiments, the recessed surface 1302 of a reinforced region 1300 may correspond to an exterior surface (e.g., exterior surface 1264, 1270, 1276) of the housing 1251 of the fluid enclosure 1248. Thus, as shown in FIG. 16, the housing 1251 of the fluid enclosure 1248 may extend for a distance 1315 (e.g., width, depth) from the interior surface 1314 of the reinforced region 1300 to the recessed surface 1302 (e.g., exterior surface of the reinforced region 1300). The ribs 1304 may then extend from the recessed surface 1302 for the distance 1305 such that the housing 1251 extends for a distance 1318 (e.g., sum of the distances 1305, 1315) in locations corresponding to the locations of the ribs 1304. As shown in the illustrated embodiment, the distance 1315 is less than the distance 1318, such that a decreased amount of material may be employed by the fluid enclosure 1248 (e.g., at least in locations corresponding to the recessed surface 1302 that does not include ribs 1304 extending therefrom). In this way, a mass associated with the fluid enclosure 1248 may be reduced, thereby decreasing manufacturing costs and improving serviceability of the fluid enclosure 1248.

As set forth above, the present disclosure may provide one or more technical effects useful in operating cooling systems (e.g., data center cooling systems) that circulate working fluid to cool electronic equipment. For example, embodiments of the present disclosure may include a chiller system that operates to cool a working fluid and circulate the working fluid between the chiller system and the electronic equipment. Said another way, at least a portion of the working fluid circuit may extend through the electronic equipment, such that certain embodiments discussed herein do not include and/or incorporate a CDU heat exchanger and/or an evaporator configured to enable heat transfer between two flows of fluid. Therefore, one or more stages of heat transfer and/or heat exchange included in some computer cooling systems is omitted, thereby enabling enhanced efficiency of the chiller system and increased heat rejection of heat generated by the electronic equipment.

Moreover, embodiments of the present disclosure may include a computer enclosure, a pressure vessel, and/or a cold plate (e.g., a fluid enclosure) having one or more reinforced regions configured to provide structural rigidity to the computer enclosure, pressure vessel, and/or cold plate while limiting an amount of material utilized to form the computer enclosure, pressure vessel, and/or cold plate. Said another way, the reinforced regions may enable a reduction in the mass of a computer enclosure, pressure vessel, and/or cold plate while still enabling retention of pressure within the interior volume of the computer enclosure, pressure vessel, and/or cold plate and resistance to deformation during operation. For example, the reinforced regions may include one or more outer ribs that extend from and along an outer perimeter of the recessed surface to define an outer boundary or perimeter of the reinforced region. The reinforced region may also include one or more interior ribs extending along and from the recessed surface in various directions. Under certain operating conditions, the interior ribs extending along and/or across the recessed surface may be configured to engage with the outer ribs to increase the structural rigidity of the computer enclosure, pressure vessel, and/or cold plate.

Additionally, the reinforced regions may be positioned at locations corresponding to sections of the computer enclosure, pressure vessel, or cold plate that are subjected to increased pressures. By employing the reinforced regions at such locations, decreased amounts of material may be utilized to form the computer enclosure, pressure vessel, and/or cold plate due to a reduced amount of material in the recessed portions of the reinforced regions. In this way, manufacturing costs of computer enclosures, pressure vessels, or cold plates may be reduced and serviceability of the computer enclosure, pressure vessel, and/or cold plate, as well as the electronic equipment disposed therein or thermally coupled thereto, may be improved. For example, the reinforced regions may enable an operator to more readily (e.g., independently) manipulate and/or service computer enclosure, pressure vessel, and/or cold plate.

While only certain features and embodiments have been illustrated and described, many modifications and changes may occur to those skilled in the art, such as variations in sizes, dimensions, structures, shapes and proportions of the various elements, values of parameters, such as temperatures and pressures, mounting arrangements, use of materials, colors, orientations, and so forth, without materially departing from the novel teachings and advantages of the subject matter recited in the claims. The order or sequence of any process or method steps may be varied or re-sequenced according to alternative embodiments. It is, therefore, to be understood that the appended claims are intended to cover all such modifications and changes as fall within the true spirit of the disclosure.

Furthermore, in an effort to provide a concise description of the exemplary embodiments, all features of an actual implementation may not have been described, such as those unrelated to the presently contemplated best mode, or those unrelated to enablement. It should be appreciated that in the development of any such actual implementation, as in any engineering or design project, numerous implementation specific decisions may be made. Such a development effort might be complex and time consuming, but would nevertheless be a routine undertaking of design, fabrication, and manufacture for those of ordinary skill having the benefit of this disclosure, without undue experimentation.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function]…” or “step for [perform]ing [a function]…”, it is intended that such elements are to be interpreted under 35 U.S.C. 112(f). However, for any claims containing elements designated in any other manner, it is intended that such elements are not to be interpreted under 35 U.S.C. 112(f).

1. A fluid enclosure for a data center cooling system, comprising:
a housing defining an interior volume, wherein the housing is configured to receive a working fluid from a working fluid circuit of a vapor compression system and direct the working fluid into the interior volume to cool electronic equipment coupled to the fluid enclosure; and
a reinforced region extending along a side of the housing, wherein the reinforced region comprises a recessed surface and one or more ribs extending from the recessed surface, and the reinforced region is configured to distribute, across the side of the housing, a pressure load imparted by the working fluid within the interior volume.

2. The fluid enclosure of claim 1, wherein the reinforced region is configured to mitigate deformation of the housing in response to an increase in the pressure load within the interior volume.

3. The fluid enclosure of claim 1, wherein the one or more ribs comprises:
a plurality of interior ribs; and
a plurality of outer ribs,
wherein the plurality of outer ribs defines a boundary of the reinforced region, and the plurality of interior ribs extends across the recessed surface to the boundary defined by the plurality of outer ribs.

4. The fluid enclosure of claim 3, wherein at least one interior rib of the plurality of interior ribs extends diagonally along the recessed surface relative to at least one outer rib of the plurality of outer ribs.

5. The fluid enclosure of claim 3, wherein the one or more ribs comprises an intermediate rib extending from a first outer rib of the plurality of outer ribs to a second outer rib of the plurality of outer ribs, and wherein an interior rib of the plurality of interior ribs abuts the intermediate rib.

6. The fluid enclosure of claim 5, wherein the intermediate rib separates the reinforced region into a first sub-section and a second sub-section.

7. The fluid enclosure of claim 5, wherein a width of the intermediate rib is greater than a width of the interior rib of the plurality of interior ribs.

8. The fluid enclosure of claim 1, wherein the fluid enclosure is a cold plate configured to thermally couple to and support the electronic equipment disposed external to the interior volume.

9. The fluid enclosure of claim 8, wherein the cold plate is configured to circulate the working fluid through the interior volume and transfer heat from the electronic equipment to the working fluid circulated through the interior volume via the housing to cool the electronic equipment.

10. The fluid enclosure of claim 1, wherein the fluid enclosure is configured to contain and support the electronic equipment disposed within the interior volume and place the working fluid within the interior volume in direct thermal contact with the electronic equipment.

11. The fluid enclosure of claim 10, wherein the reinforced region is configured to align with and protect a chip cavity defined by the housing.

12. The fluid enclosure of claim 1, wherein the housing comprises cast aluminum defining the reinforced region.

13. A data center cooling system, comprising:
a chiller system comprising a vapor compression system configured to cool a working fluid and circulate the working fluid along a working fluid circuit of the vapor compression system; and
a fluid enclosure disposed the working fluid circuit, wherein the fluid enclosure is configured to receive the working fluid and place the working fluid in a heat exchange relationship with a computer component disposed within or externally coupled to the fluid enclosure, wherein the fluid enclosure comprises a housing having a reinforced region configured to distribute a pressure load across a side of the housing.

14. The data center cooling system of claim 13, wherein the reinforced region comprises a recessed surface and a plurality of ribs extending from the recessed surface.

15. The data center cooling system of claim 14, wherein the plurality of ribs comprises one or more outer ribs defining a boundary of the reinforced region, an intermediate rib extending from a first outer rib of the one or more outer ribs to a second outer rib of the one or more outer ribs, and one or more interior ribs extending along the recessed surface to the one or more outer ribs, the intermediate rib, or both.

16. The data center cooling system of claim 13, wherein the housing comprises a plurality of sides including the side, the plurality of sides collectively defines an interior volume of the housing, a first side of the plurality of sides is a top side of the fluid enclosure, a second side of the plurality of sides is a bottom side of the fluid enclosure, a third side of the plurality of sides is a lateral side of the fluid enclosure, and respective widths of the top side and the bottom side are less than a width of the lateral side.

17. The data center cooling system of claim 13, wherein the reinforced region is a geometric structure comprising a truss structure, a monocomb structure, or both, and wherein the fluid enclosure comprises a cast material, and the cast material is aluminum.

18. A fluid enclosure of a data center cooling system, comprising:
a housing configured to be disposed along a working fluid circuit of the data center cooling system, receive a working fluid circulated through the working fluid circuit, and transfer heat from an electronic component of a data center to the working fluid;
a reinforced region of the housing, wherein the reinforced region comprises:
a recessed surface; and
a plurality of ribs extending from and along the recessed surface, wherein the plurality of ribs comprises:
a set of outer ribs defining a perimeter of the reinforced region; and
a set of interior ribs extending along the recessed surface from a first outer rib of the set of outer ribs to a second outer rib of the set of outer ribs, wherein the reinforced region is configured to distribute a pressure load imparted by the working fluid within the housing across a side of the fluid enclosure.

19. The fluid enclosure of claim 18, wherein the housing is configured to be disposed within a server rack of the data center, the housing defines an interior volume configured to receive the working fluid circulated through the working fluid circuit, the housing is configured to couple to and support the electronic component disposed external to the interior volume, and the housing is configured to transfer heat from the electronic component to the working fluid via at least one side of the housing.

20. The fluid enclosure of claim 18, wherein the housing is configured to be disposed within a server rack of the data center, the housing defines an interior volume configured to receive the working fluid circulated through the working fluid circuit, the housing is configured to couple to and support the electronic component disposed within the interior volume, and the housing is configured to direct the working fluid through the interior volume to place the working fluid in direct thermal contact with the electronic component.
